(19) United States
(12) Patent Application Publication
(10) Pub. No.: US 2003/0104649 A1
(43) Pub. Date: Jun. 5, 2003

(54) Method for making CMOS-based monolithic micro electromechanical system (MEMS) integrated circuits and integrated circuits made thereby

(76) Inventors: Mehmet Ozgur, Reston, VA (US); Mona Elwakkad Zaghloul, Bethesda, MD (US)

Correspondence Address: Roylance, Abrams, Berdo & Goodman, L.L.P., 1300 19th Street, Suite 600, Washington, DC, 20036, US

(21) Appl. No.: 10/218,902

(22) Filed: Aug. 15, 2002

Related U.S. Application Data
(60) Provisional application No. 60/312,090, filed on Aug. 15, 2001.

(51) Int. Cl. H01L 21/00; H01L 29/82; H01L 29/00

(52) U.S. Cl. 438/50; 257/415; 257/416; 257/417; 257/532; 438/53

(57) ABSTRACT

A method is provided for fabricating a CMOS based micro-electromechanical system (MEMS) integrated circuit. A CMOS circuit layout is fabricated on a silicon substrate. A first thick film photo resist layer is then deposited on the CMOS circuit layout. To prevent oxidation from occurring between aluminum and gold, a seed layer is applied to the first thick film photo resist layer. A mold is then formed by selectively depositing a second thick film photo resist layer on portions of the seed layer so that a conductive layer can be applied to the mold. Portions of the seed layer are then removed and a stress compensation material is applied to the conductive layer. A back side surface of the silicon substrate is then etched to remove areas not covered by a mask, and the first thick film photo resist layer is removed via openings in the CMOS circuit layout.

This application was made with United States Government support under Grant No. N66001-00-1-8904 awarded by the Department of the Navy. The U.S. Government has certain rights in the invention.

### CROSS REFERENCES TO RELATED APPLICATIONS

This application claims benefit under 35 U.S.C. §119(e) from U.S. Provisional Patent Application Serial No. 60/312,090 filed on Aug. 15, 2001, the entire contents of said application being expressly incorporated herein by reference.

### FIELD OF THE INVENTION

The present invention relates generally to integrated circuit fabrication, and more particularly to a method and system for providing complementary metal-oxide semiconductor (CMOS) based monolithic micro electromechanical system (MEMS) integrated circuits (ICs).

### BACKGROUND OF THE INVENTION

Silicon technologies, for example CMOS and BiCMOS are traditionally viewed as analog and digital electronic processing mediums. However, this view has begun to change with the introduction of MEM technology. MEM technology allows the integration of electrical and mechanical components on the same IC. Critical to this definition is that MEMS has both device and fabrication aspects. There are several MEMS fabrication techniques currently in widespread use, including bulk and surface micromachining, thick-film processing, molding, and electro-forming. The fabrication of a monolithic MEMS device with integrated mechanical and electrical systems requires a mass-fabrication process, which combines several of these MEMS fabrication techniques with standard thin-film process modules.

The thin-film process modules are well-developed technologies such as CMOS, BiCMOS, bipolar fabrication technologies. Although these modules are fairly sophisticated with as much as 200 process steps, essentially, they consist of several photolithographic steps after initial ion implantation and oxidation. Controlled deposition of a thin-film and its patterning assures the fabrication of thin-films at precise locations with desired electrical properties. Despite the considerable number of steps, the semiconductor industry equipped with electronic design automation (EDA) tools is very successful in obtaining consistent fabrication results. Semiconductor revenues for these processes were estimated to be more than $150 billion for 1999.

On the other hand, there are a few established monolithic MEMS process modules available. Moreover, only two types of modules are capable of monolithic integration of both electronic and mechanical systems. These two modules are iMEMS developed by Analog Devices and Digital Micro-mirror Device (DMD) technology developed by Texas Instruments. Both technologies use CMOS (or BiCMOS) technology as a base process module, and add a single film of a surface micromachined layer. Unfortunately, both technologies were developed for specific applications. Therefore, the capabilities of both technologies are limited to those specific applications. For example, DMD is used for digital micromirror displays and is marketed for projection displays. The device consists of an array containing millions of electrostatically controlled tiltable mirrors, plus circuitry, fabricated on a single silicon chip.

Another example of MEMS technology serving a specific application is the thermal ink-jet printer module. The thermal inkjet printer module is a self-contained print head that packages silicon MOS control circuitry and resistance heaters with micromachined orifices through which ink droplets are ejected. Degrees of resolution and speed are achived which are impossible to achieve with traditional technology.

A further example of MEMS technology serving a specific application is an airbag-release module for automobiles. The crash-detection device combines silicon micromachined accelerometers with electronics for triggering airbag inflation. The modules are produced in large quantities, and at least one version monolithically integrates electronic and mechanical functions on a single chip.

First generation commercial MEM processes utilize surface micromachining, which fabricates micromechanical structures from deposited thin films. First generation commercial MEMS was originally employed for integrated circuits. These films were composed of materials such as low-pressure chemical-vapor-deposition polycrystalline silicon, silicon nitrite, and silicon dioxides which could sequentially be deposited and selectively removed to build or “machine” three dimensional structures whose functionality typically required that they be free from the planar substrate.

Sandia National Labs' SUMMIT and Integrated MEMS (IMEMS), and University of California at Berkeley (UCB)'s Modular Monolithic MEMS Technologies are more advanced surface micromachining technologies, but neither were available commercially as of January 2000. These technologies employ thick structural-polysilicon films to realize mechanical systems. The integration of low-stress polysilicon films is a significant challenge, since the process needs annealing temperatures in excess of 800° C.

In contrast, in the IMEMS process, this problem is solved by fabricating the mechanical structures before the electronic circuits. On the other hand, the UCB modular monolithic MEMS technology approach substituted the metallization in the electronics portion of the system with tungsten, which can withstand the elevated annealing temperatures.

Despite the improvements in surface micromachining techniques, such MEMS process modules have limited applications. Although several revolutionary devices have been fabricated by surface micromachining, all of these devices need mechanical freedom for their functionality. Therefore, the processes, in which these devices are fabricated, can be classified as low-frequency MEMS processes. In contrast high frequency applications, for example, radio-frequency (RF) applications such as mobile communications have different requirements. One of the requirements is the integration of active and passive RF circuits. The quality requirements of the high frequency components can only be met by using additional MEMS techniques.

The quality of passive RF devices is improved by decreasing the dielectric and conductor losses. The dielectric losses can be minimized either by increasing the distance between the device and substrate or by removing the substrate. Generally, the latter of these options is preferred. The etching step, which achieves this result, is called bulk micromachining. The available etching methods fall into three categories in terms of the state of the etchant: wet, dry, and plasma.

The integration of active and passive RF circuits is far more difficult than the similar challenge encountered in low-frequency MEMS processes. The main problem is that the traditional silicon-based IC processes are limited by the low electron mobility in the silicon. The lack of speed in silicon has led to the development of alternative thin-film processes based on exotic materials such as GaAs, SiGe, and InAs and the like. However, with the exception of SiGe technology, these new technologies are considerably more expensive than silicon based technologies. Therefore, those designs have never reached the same level of integration.

Passive microwave systems are designed with distributed elements, which are, generally, very large. Consequently, the fabrication of integrated systems is very expensive at high frequencies. In practice, only very important passive components are integrated with the active devices. Others are manufactured on low-cost microwave substrates. Currently, the cost-optimized solution is based on chip level integration on the microwave substrates.

The high frequency MEMS processes under development follow the same trend of not being able to meet the need for a low cost monolithic IC that is not necessarily application specific.

The combination of new and old fabrication techniques has proved to be very promising for the electronics industry. However, the development of a highly functional processes that can manufacture products with a variety of functions is still required. These processes must produce not only traditional VLSI circuits and memories but also devices such as sensors, actuators, microfluidic, optical and reconfigurable RF components.

None of the commercial and educational institutions with MEMS processes under development or in production are capable of integrating the wide variety of mechanical and electrical components in a single process without requiring an application specific function. Thus, industries like the communications industry which require the integration of mechanical and electrical components on an IC to meet the growing need for broadband, are in great need of a monolithic integrated MEMS process.

### SUMMARY OF THE INVENTION

An object of the present invention is to provide a method capable of effectively and efficiently processing the manufacture of CMOS based monolithic micro electromechanical integrated circuits. Therefore, a method is provided for fabricating a CMOS based micro-electromechanical system (MEMS) integrated circuit. A CMOS circuit layout is fabricated on a silicon substrate. A first thick film photo resist layer is then deposited on the CMOS circuit layout. To prevent oxidation from occurring between aluminum and gold, a seed layer is applied to the first thick film photo resist layer. A mold is then formed by selectively depositing a second thick film photo resist layer on portions of the seed layer so that a conductive layer can be applied to the mold. Portions of the seed layer are then removed, and a stress compensation material is applied to the conductive layer. A back side surface of the silicon substrate is then etched to remove areas not covered by a mask.The first thick film photo resist layer is removed via openings in the CMOS circuit layout.

### BRIEF DESCRIPTION OF DRAWINGS

These and other objects, advantages and novel features of the invention will be more readily appreciated from the following detailed description when read in conjunction with the accompanying drawings, in which:

FIG. 1 is a cross sectional view of a complementary metal-oxide semiconductor (CMOS) based micro electromechanical system (MEMS) integrated circuit fabricated in accordance with an embodiment of the present invention;

FIG. 2 is a cross sectional view of a CMOS fabricated IC including an open area for silicon micromachining constructed in accordance with an embodiment of the present invention;

FIG. 3 is a patterned first layer of a thick film photoresist (TFPR) applied in accordance with an embodiment of the present invention;

FIG. 4 is a spin curve for a TFPR used in accordance with an embodiment of the present invention;

FIG. 5 is a conventional TFPR profile of a tunable capacitor;

FIG. 6 is a cross sectional view of a CMOS fabricated IC including a chromium and gold seed layer fabricated in accordance with an embodiment of the present invention;

FIG. 7 shows the patterned first layer of FIG. 3 having a second layer of a thick film photoresist for use as a mold and constructed in accordance with an embodiment of the present invention;

FIG. 8 shows the patterned second layer of the thick photo resist of FIG. 7 having a gold electroplated layer in accordance with an embodiment of the present invention;

FIG. 9 shows an electroplating arrangement constructed in accordance with an embodiment of the present invention;

FIGS. 10A and 10B show profiles of the gold plated areas of a sample wafer in accordance with an embodiment of the present invention;

FIG. 11 is a graph showing the plating differences for different areas on the wafer of FIG. 10A in accordance with an embodiment of the present invention;

FIGS. 12A and 12B together show the one dimensional flow on the surface of the MEMS IC of FIG. 1 in accordance with an embodiment of the present invention;

FIG. 13 shows the MEMS IC with the seed layer removed in accordance with an embodiment of the present invention;

FIG. 14 shows the polymide layer applied to the monolithic MEMS IC of FIG. 1 in accordance with an embodiment of the present invention;

FIGS. 15A through 15C show various techniques used to handle stress on a suspended membrane in accordance with an embodiment of the present invention;

FIGS. 16A and 16B show pre and post bulk micro machining processing on the MEMS IC membrane in accordance with an embodiment of the present invention;

FIG. 17 shows the MEMS IC with the first thick film photo resist TFPR layer removed in accordance with an embodiment of the present invention;

FIGS. 18A and 18B together show the layout of a tunable capacitor constructed in accordance with an embodiment of the present invention;

FIG. 19 shows different mask patterns used to fabricate the MEMS IC in accordance with an embodiment of the present invention;

FIG. 20 shows a two dimensional profile of the MEMS IC in accordance with an embodiment of the present invention;

FIG. 21 shows a patterned second thick film photo resist layer in accordance with an embodiment of the present invention;

FIGS. 22A and 22B show the mechanical layout of a tunable capacitor constructed in accordance with an embodiment of the present invention;

FIG. 23 shows the surface profile of an actuated second metal plate for the tunable capacitor in accordance with an embodiment of the present invention;

FIG. 24 shows an actuated plate of the mechanical capacitor modeled as a fixed fixed beam (FFB) in accordance with an embodiment of the present invention;

FIGS. 25A and 25B together show a simplified and detailed cross sectional view of the FFB in accordance with an embodiment of the present invention;

FIG. 26 shows an equivalent electrical circuit for the tunable capacitor in accordance with an embodiment of the present invention;

FIG. 27 shows a graph of the capacitance per unit length for the tunable capacitor in accordance with an embodiment of the present invention;

FIGS. 28A and 28B together show the capacitance ratio compared to the size of the plates of the capacitor in accordance with an embodiment of the present invention;

FIGS. 29A and 29B together show the relationship between plate distances and capacitance for the tunable capacitor in accordance with an embodiment of the present invention;

FIG. 30 shows the tunable capacitor prior to post processing fabrication in accordance with an embodiment of the present invention;

FIGS. 31A and 31B together show parasitic elements for the tunable capacitor in accordance with an embodiment of the present invention;

FIGS. 32 is a graph of the measurement and curve fit for the tunable capacitor in accordance with an embodiment of the present invention;

FIG. 33 is a graph of the measured capacitance change obtained from the tunable capacitor in accordance with an embodiment of the present invention;

### DETAILED DESCRIPTION OF THE PREFERRED EMBODIMENTS

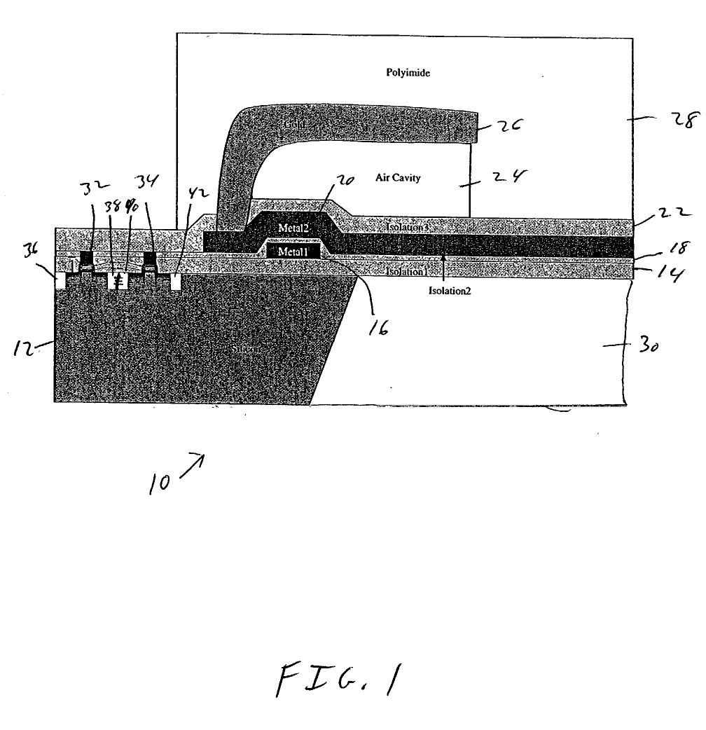

FIG. 1 is a cross sectional view of a complementary metal-oxide semiconductor (CMOS) based monolithic micro electromechanical system (MEMS) integrated circuit 10 fabricated in accordance with an embodiment of the present invention. The monolithic MEMS IC 10 comprises a silicon layer 12 also known as a substrate, a first isolation layer 14, a first metal layer 16, a second isolation layer 18, a second metal layer 20, a third isolation layer 22, an air cavity portion 24, a gold metal layer 26, a polymide layer 28, an open portion 30 of the silicon layer 12 which is also known as a substrate, first and second gates 32 and 34, first and second sources 36 and 38 and first and second drains 40 and 42. It should be appreciated that although first metal layer 16, second metal layer 20 and gold metal layer 26 are described as layers, the layers become plates during different stages of the MEMS IC fabrication process. For example, the first metal layer 16 is formed into an aluminum plate having contact pads.

It should be noted that the monolithic MEMS IC 10 can be fabricated to include but is not limited to CMOS analog and digital circuits, sensors based on piezoresistive, thermal or mechanical effects, actuators based on electrostatic and thermal effects, mechanical systems, integrated passive and active micro-fluidic components, passive RF components having operating frequencies up to 60 GHz, and reconfigurable systems. These various circuits are assigned to type I, II, III and IV devices as is known in the art.

The monolithic MEMS IC 10 will now be described with reference to its novel features. Specifically, the open portion 30 of the silicon layer 12 provides flexibility to the first isolation layer 14, the second isolation layer 18, the second metal layer 20, and third isolation layer 22 allowing them to move with respect to the MEMS IC 10 without affecting the structural integrity of the MEMS IC 10. The polymide layer 28 provides structural support to the gold layer 26.

In an embodiment of the invention, by adjusting the distance between the gold metal layer 26 and first metal layer 16 and/or second metal layer 20 different mechanical components can be simulated, e.g., a tunable capacitor.

In another embodiment of the invention, by changing the thicknesses of the materials used in FIG. 1, mechanical components having different properties can be achieved. For example, Table 1 lists preferred thicknesses for the materials used in FIG. 1.

TABLE 1

| | t | | ? |
|---|---|---|---|
| Material | μm | eᵣ | O.cm |
| Silicon | >300 | 11.70 | <10 |
| first isolation layer | 1.65 | 3.90 | — |
| first metal layer | 0.60 | — | 3 × 10⁻¹⁰ |
| (metal1) | | | |
| second isolation layer | 0.75 | 3.90 | — |
| second metal layer | 1.00 | — | 3 × 10⁻¹⁰ |
| (metal2) | | | |
| third isolation layer | 1.00 | 3.90 | — |
| Polymide | >50 | >2.4 | — |
| Air cavity | >10 | 1.00 | — |
| Gold metal layer | >3.0 | — | 1 × 10⁻¹⁰ |

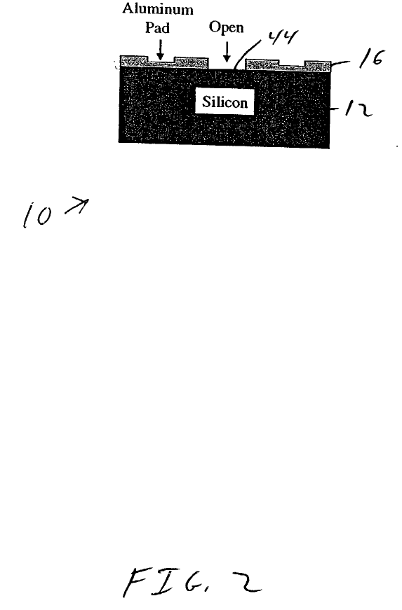

FIG. 2 is a cross sectional view of a CMOS fabricated IC including an open area for silicon micromachining constructed in accordance with an embodiment of the present invention. Specifically, FIG. 2 depicts the monolithic MEMS IC 10 having the first metal layer 16 disposed on the silicon layer 12. Although not shown, a CMOS membrane is disposed on top of the silicon layer 12. The first metal layer 16 is preferably comprised of aluminum and includes at least one open portion 44. The open portion 44 of the first metal layer 16 is fabricated by several vias stacked in interlayer dielectric layers to form an access hole to the silicon layer 12 and provides for the removal of a portion of the silicon substrate 12 from the front side of the MEMS IC 10. In addition, the open portion 44 of the MEMS IC 10 is also useful in maskless IC fabrication.

The silicon layer 12 for the monolithic MEMS IC 10 is fabricated using preferably two analog CMOS fabrication processes. A first layer comprising preferably a 2.0 μm double poly/double metal is applied to the MEMS IC 10. Then a second layer comprising preferably a 1.2 μm double poly/double metal is applied to the MEMS IC 10.

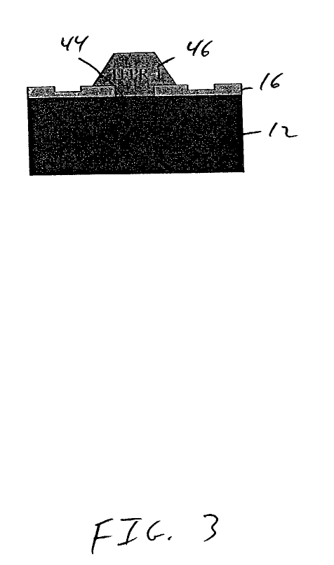

FIG. 3 shows a thick film photo resist (TFPR) layer 46 covering the opening 44 in the first metal layer 16. Thick film processing is necessary to fabricate type II, III, and IV devices using CMOS processing and comprises a layer of thick film photoresist which is used to define cavities requiring the operation of the Type II, III, and IV devices. In many cases, the first thick film photoresist layer 46 is used as a sacrificial layer to cover the opening in the first metal layer 16.

In one embodiment of the invention, preferably a TFPR with the trade name AZ-4562, manufactured by AZ Electronics, Inc. of Germany is used as the first thick film photoresist layer 46. The AZ-4562 is applied on 4 inch wafers. The AZ-4562 gives extremely smooth surfaces compared to the other commercial TFPRs due to a special solvent in the solution. In another embodiment of the invention, preferably a TFPR with the trade name AZ-P4620 manufactured by AZ Electronics, Inc. is used as the first thick film photo resist layer 46. The AZ-P4620 includes a safer solvent than the AZ-4562, and is more readily available. However, based on safety concerns, the AZ-P4620 is the preferred solution to be used as the first thick film photo resist layer 46 in the fabrication of the MEMS IC 10.

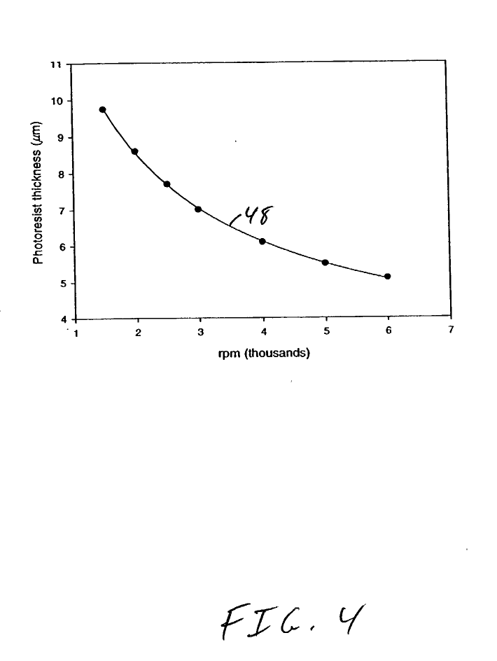

The spin curve for the AZ-P4620 is given in FIG. 4. where plot 48 shows that as the rpm increases the thickness for the thick film photo resist is reduced. The thickness of the AZ-P4620 can be measured by using a non-contact profiler with the trade name Wyko RST-Plus, manufactured by Veeco, Inc. after a thin layer of gold is evaporated on top of the first thick film photo resist layer 46. The thicknesses provided are hard to repeat at low rpm levels e.g., at less than 1500 rpm. For wafer processing, spin rates higher than 2500 rpm are preferred. Thicker coatings up to 50 μm can be achieved by simply repeating the single-coat procedure.

It should be noted that the photo-lithographic processing of a single die is significantly more difficult and less repeatable compared to wafer level processing. The problem stems from the fact that the dies should be handled manually during every step, whereas the wafers are preferably handled using special equipment. Additionally, the uniformity of the photoresist film is degraded due to the edge effect. Minimization of edge beads can only be accomplished by increasing the spin speed. However, this decreases the thickness of the first thick film photo resist layer 46.

Different thicknesses preferably between 5 μm and 15 μm can be used for the first thick film photo resist layer 46. If first thick film photo resist layer 46 is thicker than 7 μm, the layer should preferably be spun in two steps. Each coat is prebaked at about 100 C for preferably 200 seconds. The first thick film photo resist layer 46 is then exposed to an ultraviolet source and developed using preferably a thick film photo resist developer with the trade name AZ-K400. For maximum resolution, the edge beads are exposed separately. The exposure time increases with the thickness of the first thick film photo resist layer 46. In general, 10 μm thick isolation layers require 400 mJ/cm² exposure, whereas edge beads usually require more than one order of magnitude more exposure.

FIG. 5 shows the profile of the first thick film photo resist layer 46 for a tunable capacitor that was fabricated using the process of the present invention. Specifically, FIG. 5 shows that the thickness of the first thick film photo resist layer 46 varies ±1 μm between 50 and 150 μm extent as shown by plot 50B. One of the reasons the roughness is this large, is based on the roughness of the starting surface. The finished CMOS surface can have steps as high as 5 μm, if no planarization techniques, e.g., chemical-mechanical-polishing (CMP), are used.

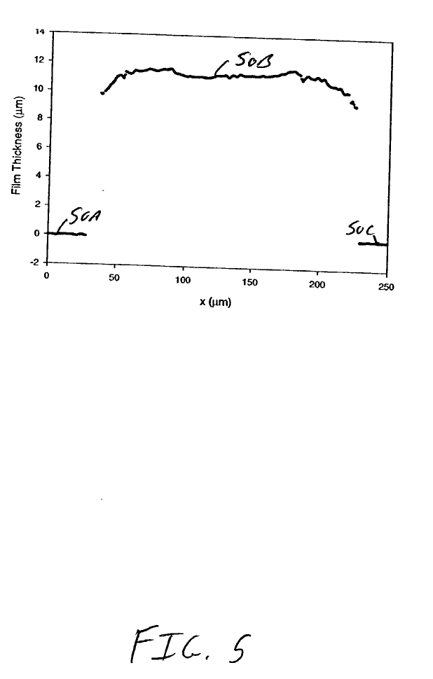

The application of a gold layer over the first metal layer 16 and the first thick film photo resist layer 46 is required. However, the direct deposition of gold (Au) over aluminum (Al) metallization does not work for several reasons. First, the adhesion between the two metals is very poor because of the indigenous aluminum oxide. The same oxide would increase the contact resistance between the two metals. Secondly, direct contact between gold and aluminum results in the formation of a brittle alloy, Al₂—Au. The formation of this compound is known in the semiconductor industry as the “purple plague” which reduces the yield of the integrated circuit. For this reason, commercially produced integrated circuits with aluminum metallization are rarely wirebonded with gold bonding wire. However, formation of the gold/aluminum alloy can be prevented by sandwiching a barrier metal layer, preferably chromium, between metals. Therefore, the deposition of chromium and gold comprises a seed layer 52, as illustrated in FIG. 6.

Prior to the deposition of the seed layer 52, the first metal layer 16 is cleaned using preferably in-situ cleaning. The object is to lower the contact resistance between the metals to preferably less than 0.1 O for a 40×40 μm area.

Since the test chips were in storage more than 6 months, the surface of the bonding pads was contaminated with unspecified organic material and the aluminum oxide was approximately 200 A thick. The organic impurities were then removed in an UV-ozone cleaning system for about 30 min.

In one embodiment of the invention, the removal of the aluminum oxide is accomplished chemically. In another embodiment of the invention the removal of the aluminum oxide is accomplished mechanically. Preferably, the oxide etch solution is buffered oxide etch (BOE) which comprises from 13 parts of NH₄F (40%) and 2 parts of HF (49%) by volume and is mixed with glacial acetic acid in the volume ratio of 3:1. This wet etch solution is not very selective to aluminum. The general practice is to clean for about 1 min.

Selectivity of the etchant used in the MEMS IC 10 fabrication process is important for the contact pads used in the CMOS fabrication portion of the process. In the trials for the fabrication of the monolithic MEMS IC 10, using diluted BOE resulted in a majority of the contact pads being severely damaged. Since first metal layer 16 is very thin, e.g., most cases less than 1.1 μm, better control of the cleaning process is required during the oxide removal. This is preferably why mechanical etching is used in the cleaning process. Due to re-oxidation of the aluminum contact pads after cleaning is performed, mechanical etching using evaporation is added into the cleaning process. This provides good electrical contacts. However, there is a concern that even low-energy ions might damage sensitive channels of CMOS transistors. Therefore, extra precaution is taken over the active circuit areas by applying a thick first thick film photo resist layer 46. By applying a thick first thick film photo resist layer 46, very high quality contacts are obtained between the first metal layer 16 and the gold layer used in the seed layer 52.

In an embodiment of the invention, chromium can be substituted with an element from the group comprising nickel (Ni), and titanium (Ti). Chromium, nickel and titanium are preferred metals based on their specific properties. For example, nickel is preferred for its electroless deposition property. Several commercially available plating solutions usually require the strict control of pH and temperature for the solution.

In another embodiment of the present invention, evaporation of the barrier metals is used as a deposition technique. Evaporation of the desired metals provides uniform coating, improved thickness control and repeatability of the results. Furthermore, evaporation is compatible with dry cleaning. Thus, it is possible to clean the surfaces and evaporate the barrier layer without breaking the vacuum. In another embodiment of the invention, chromium (Cr) is preferably used as a barrier metal between Al and Au with 75 to 250 A thick Cr evaporated after surface cleaning. In thick-film processing, the steps that should be covered with such thin films can be more than 25 μm high. Therefore, it is preferable to have good coverage even in extreme cases.

In another embodiment of the invention, preferably 800-3000 A thick gold is evaporated by using in-situ cleaning. Since coverage is very important for the electroplating process, thicker values are preferred.

The seed layer 52 is used to electroplate much thicker gold strips on the chip. Unlike conventional photolithographic techniques, the electroplating procedure requires a mold to define the patterns. The mold restricts the chemical reaction of specified areas of the chip where the seed layer is in contact with reactants. For molding purposes, TFPRs are commonly used. To achieve successful deposition of thick films, the photoresist and seed layer must be inert to the plating solution. Although cyanide and sulfite-based, gold-plating solutions are used to fabricate the monolithic MEMS IC 10, other combinations can be used without departing from the scope of the present invention.

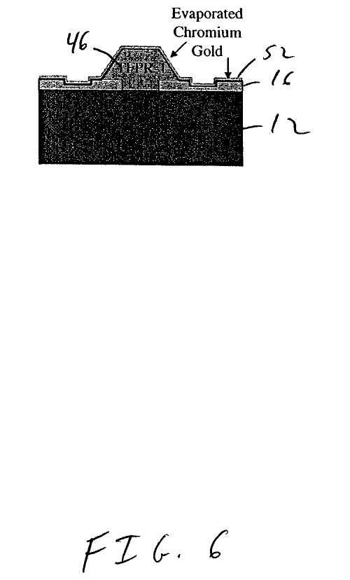

The present invention will now be discussed with reference to FIG. 7. FIG. 7, shows a second thick film photo resist layer 54 overlaid over the seed layer 52. The second thick film photo resist layer 54 is preferably thicker than the first thick film photo resist layer 46. Therefore, preferably multiple-coats of AZ-P4620 is used to provide the second thick film photo resist layer 54. However, the thickness of the second photo resist layer is restricted because the thicker the mold, the lower the resolution. This is due to the limited aspect ratio that can be obtained with AZ-P4620.

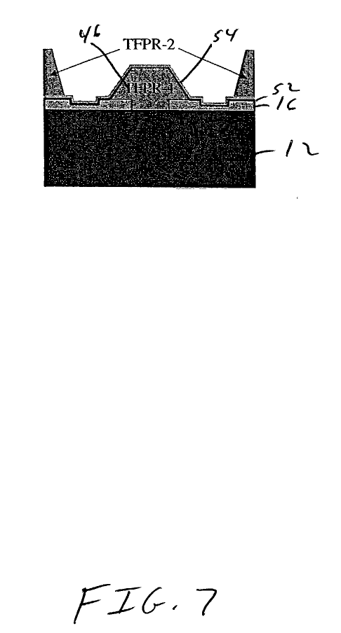

Electroplating is necessary to deposit thick films of gold on CMOS chips. The electroless deposition and evaporation of gold is preferably limited to thicknesses less than 1 μm as shown in FIG. 8. The eletroplated gold forms the gold layer 26. In an embodiment of the invention, sputtering is used to apply the gold to the MEMS IC 10. However, although sputtering provides for the deposit of thicker films or layers, in many cases, it is not practical due to its high cost and susceptability to contamination.

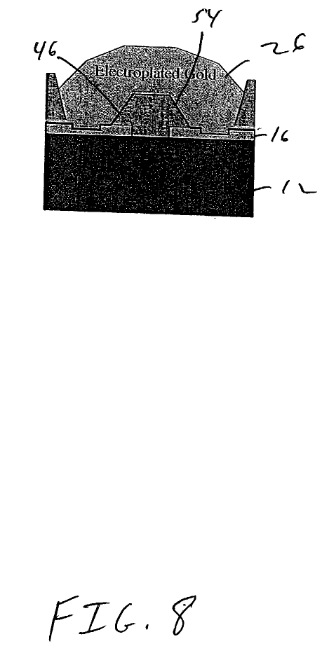

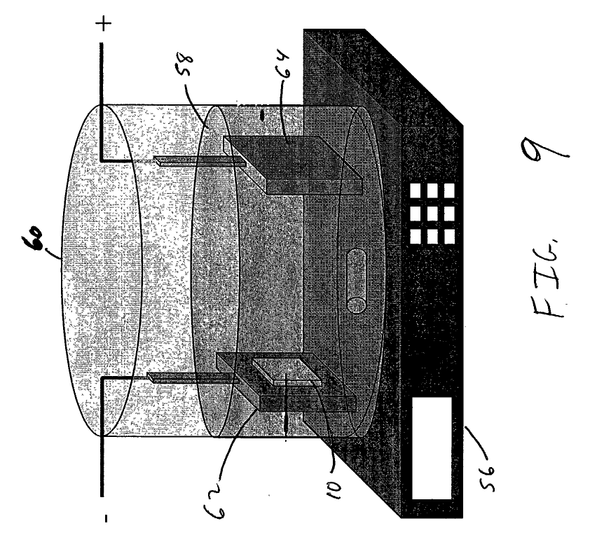

On the other hand, as illustrated in FIG. 10, the MEMS IC 10 can be electroplated using a container 60, a plating solution 58, a hot plate stirrer 56, a cathode 62 immersed in the platting solution 58 and connected to the MEMS IC 10 on one end and to the negative polarity of a power supply (not shown) at the other end. An anode 64 is immersed in the plating solution 58 at one end and connected to the negative polarity of the power source. The cathode 62 preferably comprises copper and the anode 64 preferably comprises platinum having an area of about 2×5.3 mm². Using this electroplating arrangement provides for the application of gold films as thick as 25 μm.

It should be noted that electroplated noble metal films have lower stresses than sputtered films, due to the larger grain sizes of the noble metal films. For example, cyanide based plating solutions, e.g., Transene SG-1 manufactured by Transene, Inc., require special handling. Transene SG-1 inhibits cellular respiration and may cause blood, central nervous system, and thyroid changes. Furthermore, it has been reported that gold cyanide solutions may penetrate the photoresist layer and, result in the cracking or dissolution of the photoresist layer. In comparison, gold-sulfite plating solutions are not sensitive to the photoresist. However a bath of gold-sulfite gradually degrades during electrolysis.

In an embodiment of the invention, a plating solution with the trade name UltraClad 710, manufactured by Ethone-Omi Inc., which is a sulfite based high-purity gold plating solution is preferably used as the plating solution. For a current density of 40-50 μA/mm² at 55-60 C with about a 400-500 rpm rigorous agitation, the plating rate has been observed as 0.2 μm/min for a 50×50 μm area, which is almost 15 μm below the surface level. The deposition of the gold layer 26, however, is limited by the diffusion in small and concealed areas.

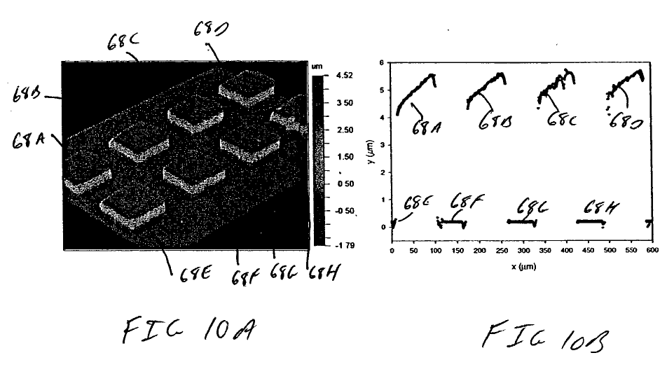

There are several parameters of the electroplating setup that need to be optimized for a specific application. One difficulty is that the plating uniformity depends on several factors. Several experiments were performed to determine the optimum plating conditions to achieve uniform plating. To demonstrate the severity of the plating non-uniformity, the surface profile of an earlier sample MEMS IC is shown in FIGS. 10A and 10B. Specifically, the sample was fabricated by evaporating chromium and gold directly on a new silicon wafer 66. A patterned 10 μm thick TFPR had 100×100 μm open areas spaced by 50 μm. The profiles before and after the seed layer were stripped are shown in FIG. 10B via plots 68A through 68H. These profiles show significant non-uniformity due to one-dimensional agitation. Similar tests with smaller features show more uniform profiles, however, the plating at the midpoints strongly depend on the minimum feature size in the direction of flow. As shown in FIG. 11, for plot 70 the plating thicknesses decrease as the feature size of the MEMS IC 10 gets smaller.

In order to get uniform plating, the plating areas exposed to the plating solution 58 must have equal current density and see an equal concentration of reaction. This condition is rather difficult to satisfy. In addition, temperature, current density, and agitation controls are equally important.

To minimize temperature changes, the plating solution 58 is placed in a larger water tank and then placed on the hot plate/stirrer 56. The temperature of the water is read via a thermocouple (not shown) and fed to the hot plate/stirrer 56. The thermal capacity of the system is too large to be handled effectively by the hot-plate/stirrer 56. Therefore, in spite of the feedback, manual control is necessary to keep the temperature of the plating solution in preferably the 58 ±3° C. range.

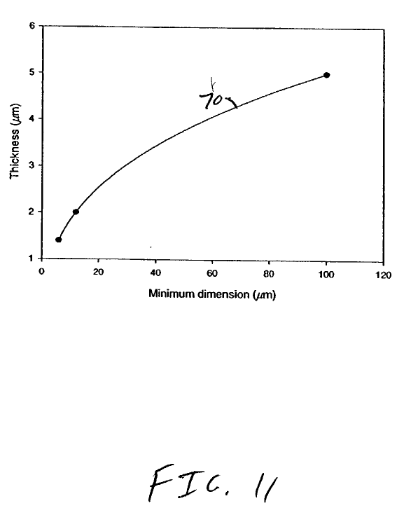

Agitation is vital for uniform electroplating. Therefore in one embodiment of the invention, a magnetic stirrer (not shown) is used to agitate the plating solution 58. However, this technique is very limited since it creates a one-dimensional flow on the surface of the MEMS IC 10. This is illustrated in FIGS. 12A and 12B. The size of the plated area and its placement with respect to the flow is important. In addition, the length of the plating pit along the flow, the depth of the pit, the speed of the flow at the top surface, the angular deviation between the planes of the cathode 62 and anode plates 64 and even other pits and their sizes relative to the considered pit become important in the final result.

An effective solution to minimize non-uniform plating due to nonuniform current distribution is to add a strip of metal (not shown) around the device to be plated to minimize the edge effects. A copper plate preferably 8.5 mm×8.5 mm is machined to hold the MEMS IC 10, which preferably has the dimensions of 5 mm×5 mm. The MEMS IC 10 is wirebonded to the center of this area. This arrangement provides for a 1.75 mm-wide metal strip around the die area for nonlinear current distribution. A similar strip exists on the surface of the MEMS IC 10 as well.

Three different techniques were investigated to alleviate the problem. First, slower speeds of agitation were considered. The speed of the agitation for the setup in FIG. 9 was measured in terms of the number of rotations per minute. The slope of the plated areas shown in FIG. 10B goes down from 1.5 μm/100 μm for 500 rpm to 0.5 μm/100 μm for 200 rpm. If the speeds are lower than 100 rpm, the surface roughness becomes a major problem and the plating rate goes down. Since increased plating time resulted in cracks in the second thick film photo resist layer 54, it is preferred to keep the plating time to less than 20 minutes.

Secondly, ultrasonic agitation was investigated as a possible agitation technique. For this purpose, the plating solution 58 was placed inside an ultrasonic cleaner, preferably model no. FS140, manufactured by Fisher Scientific Inc. The experiments were unsuccessful because the cleaner does not allow for control of the power level of the ultrasonic agitation. And the available level of the power was so high that in less than 5 minutes the second thick film photo resist layer 54 was locally removed e.g., at cavitation points. However, this is still a feasible technique at low power levels and with a proper ultrasonic source(s).

It is possible to achieve uniform plating profiles using a magnetic stirrer by controlling the speed of the rotations and the angle between planes of the electrodes. While the speed is varied between 200-500 rpm, the angle is changed between −45° and 45° for every two minutes. This technique gives less than 0.2 μm/100 μm slope, smooth surfaces and less than 20 minutes plating times for about 7 μm thick gold.

A fundamental assumption in the plating process outlined above is that the plating surface is planar and similar structures are placed relatively far away. However, often the actual plating environment does not meet this criteria.

The seed layer 52 is preferably stripped after the plating process. This is accomplished by using wet etching of the second thick film photo resist layer 54, and the seed layer 52. High selectivity of the etchants is preferred. Even if such etchants are available, several factors may cause unwanted damage to other structures. The stripping completes the fabrication of low-loss, high quality metallization that is much superior to anything available in CMOS. Such low-loss layers are very important for passive RF devices necessary for mobile applications. The desired levels of sheet resistance is less than 0.01 O/sq.

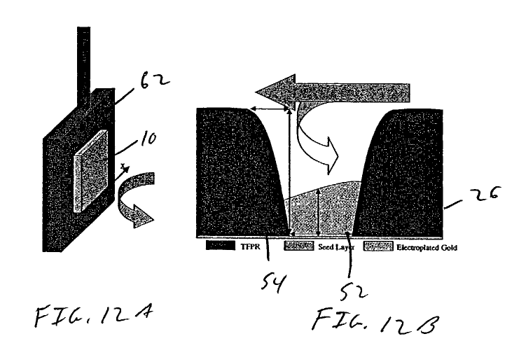

The second thick film photo resist layer 54 is stripped with acetone. If the thickness of the seed layer 52 is less than 1000 A or its coverage is not good enough, acetone might dissolve the first thick film photo resist layer 46. The evaporated gold in the seed layer 52 is stripped using potassium iodide (KI). Potassium iodide has different etching rates for electroplated and evaporated gold. Because of the non-planarity of the surface longer than normal etching cycles are required to remove the gold in the seed layer 52. Finally, the chromium in the seed layer 52 is removed using a CR-7 mask etchant. During the stripping process a severe attack of CR-7 to the plated gold and exposed aluminum contact pads occurred. The quality of the final geometry is limited based on the selectivity of the wet etchants used during the stripping process. After the chromium etch, the plated gold was noticeably softer. Probing of such areas is extremely difficult, and electrical contacts are not reliable and reproducible. FIG. 13 illustrates the cross-sectional view of the post-processed MEMS IC 10.

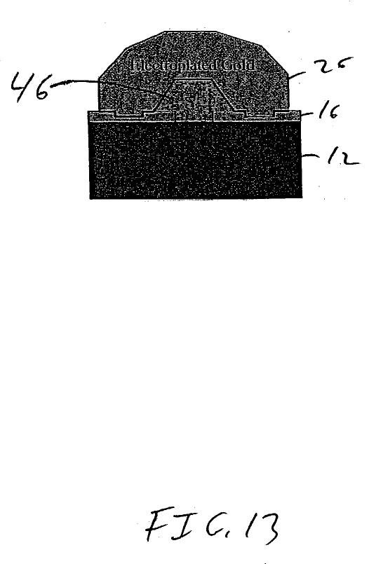

Fabrication of planar and mechanically robust membranes is very important for microwave applications. Internal stresses of the CMOS films that comprise the suspended membrane is large enough to cause mechanical problems, especially in large, for example less than 200×200 μm, membranes having only SiO₂ layers. Even in successfully suspended structures, the membranes buckle, which complicates the design of high-frequency devices such as coupled lines with very small spacing. Furthermore, the internal stress in the individual standard CMOS layers has been a reliability issue for a long time. Many measures have been taken to minimize this stress to improve the reliability in recent CMOS processes. Despite these efforts, the internal stresses in these layers remain considerably larger than what is required for robust planar suspended membranes with large areas. These problems are solved by depositing a stress-compensation layer on top, prior to the release of the beam by bulk-micromachining. FIG. 14 shows one type of compensation used in the fabrication of the MEMS IC 10. Specifically, the polymide layer 28 is applied to the MEMS IC 10.

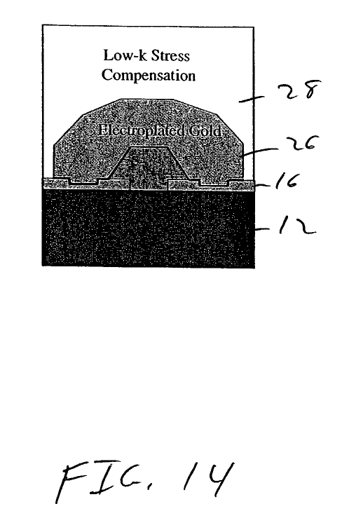

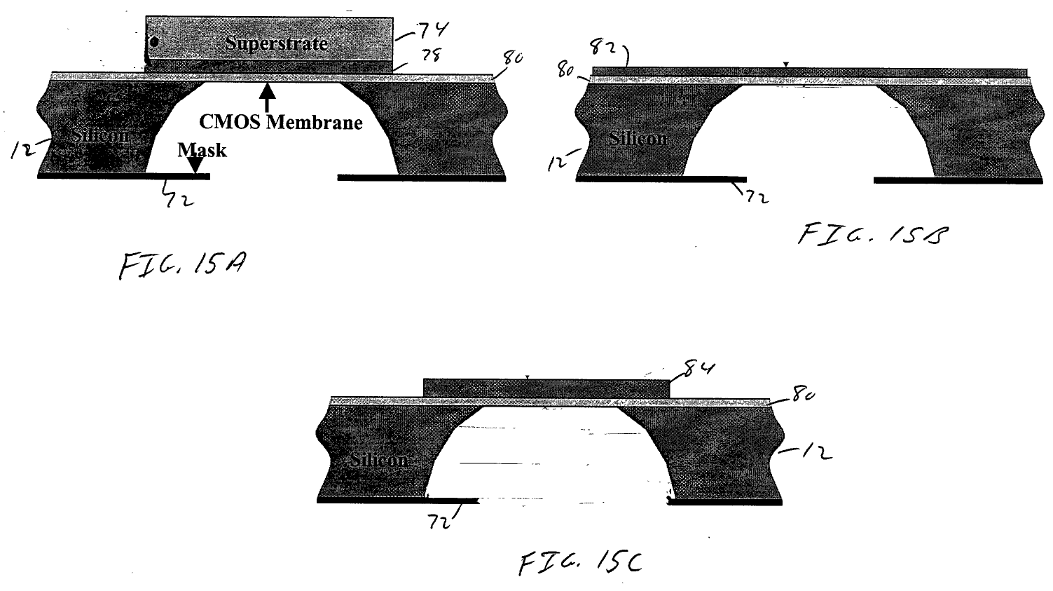

Three different embodiments have been used to provide stress-compensation of the suspended membranes. The three embodiments of the invention are illustrated in FIGS. 15 through 15C. In the first embodiment of the invention, a superstrate 74 is bonded via an adhesive 78 to the area to be suspended. The superstrate 74 can be any low-loss microwave material. In experiments, different types of glasses were used as a superstrate. The first samples of integrated multi-purpose power sensors were fabricated using this procedure. A 150 μm thick glass substrate can be placed on microwave components, for example, an antenna matching network, a filter, and a termination, minimizing the unsupported suspended area required for a power converter.

Stress compensation via bonding the superstrate 74 to an area to be suspended is not ideal since it does not lend itself to mass-fabrication. In many cases, special adhesives are used for bonding since the microwave properties of the component to be fabricated is important. This leads to investigation of the other two stress-compensation techniques. The second embodiment of the invention is shown in FIG. 15B. A carefully deposited thin silicon nitride (SiN) layer 82 is placed on the suspended membrane 80 under tensile stress. Multiple coatings are necessary using the 1.2 μm CMOS technology.

FIG. 15C shows another embodiment of the invention to provide stress compensation. A single thick layer 84 is screen-printed on the membrane area. This is advantageous because compensation with thin SiN films requires a high-resolution mask to obtain electrical contacts. However, if the compensation is performed by screen-printing, then the film can be deposited on the membrane 80 area only. This eliminates the need for an additional high-resolution mask. The size of membranes needed for microwave purposes is usually large e.g., 1 mm×1 mm, and resolution of screen-printing e.g., a 10 μm feature size and 20 μm placement accuracy, is adequate. Therefore, stress-compensation by screen-printing is more cost-effective compared to thin-film techniques.

In this post-processing procedure, the use of thick film stress-compensation is advantageous. Particularly, it is necessary to have large cavities for the operation of some of the devices, such as tunable capacitors, switches and microfluidic components. A thick layer can perform various functions besides stress-compensating the large CMOS membranes required for microwave operation. For example, it can be used to fabricate reconfigurable microwave components by supporting an additional layer of metallization. It is also possible to have high quality gold plated microfluidic structures supported by this layer to fabricate microfluidic devices or sensors.

A polymide with the trade name Epo-tek 600, manufactured by Epoxy Technology, Inc., is preferred as a compensation material because of its excellent electrical and mechanical properties. Increasing the film thickness caused curing problems. If the recommended curing cycle e.g., 1 hour prebake at 150° C. followed by 30 minutes final cure at 275° C., is used for film thicknesses above 300 μm, the stress-generated cracks are observed. The optimum thickness of the polyimide film varies with the application. Nonetheless, for most of the microwave circuits that do not contain any microfluidic components, the optimum thickness is preferably about 200 μm. Without any change in the curing procedure, a smooth, uniform, pin-hole and crack free polyamide films can be obtained on CMOS chips by applying multiple coats of polymide. Each coating is cured with the same procedure described above. Electrical properties of the polyimide changes with processing. Therefore, the curing procedure should be followed closely to obtain the same properties. An optimum fabrication should yield films with dielectric constants as low as 2.4. Low dielectric constant films are desirable for low-dispersion microwave propagation.

Table 2 provides a comparison between polymide and benzocyclobutene (BCB).

TABLE 2

| | | BCB |
|---|---|---|
| | Polyimide | (Benzocyclobutene) |
| Dielectric Constants | 2.4-3.3 | 2.7 |
| Loss Tangent (@ 1 MHZ) | 0.0004 | 0.0008 |
| Curing Temperature (° C.) | 275 | 250 |
| Breakdown Voltage (V/cm) | 3 × 10⁶ | 3 × 10⁶ |
| CTE (ppm/° C.) | 5-40 | 52 |
| Thermal Conductivity (W/m ° K.) | 0.12 | 0.29 |
| Residual Stress (MPa) | 10-43 | 28 |
| Tensile Strength (MPa) | 175 | 87 |
| Film Thickness (μm) | <30 | <30 |

Polyimides are high temperature engineering polymers originally developed by the DuPont Company. When compared to most other organic or polymeric materials, polyimides exhibit an exceptional combination of thermal stability e.g., greater than 500° C., mechanical toughness and chemical resistance. Because of their high degree of ductility and inherently low CTE, polyimides can be readily implemented into a variety of microelectronic applications. Polymides with the trade names DuPont Pyralin series and Epo-Tek 600 are popular in stress-buffer coating of silicon wafers.

There is another class of polymers derived for low-k microelectronics applications. The Cyclotene series by Dow Chemical Company are derived from B-staged bisbenzocyclobutene (BCB) chemistry. They are particularly good for thin film applications such as interlayer insulators. Both of these materials are investigated because of their low dielectric constants, which is desired for microwave applications. A brief comparison is included in Table 2.

The back side of the silicon layer 12 is patterned by using standard photolithographic techniques. Shipley 1813 positive photoresist is used in the back side patterning and in the front side protection during etching. Spinning speeds higher than 5000 rpm are used during the preparation of the samples. The polymide film 28 should be protected by using multilayer coating. A simple photolithographic preparation is good enough for bulk micromachining with xenon-difluoride (XeF₂). If wet type of bulk micromachining is needed then appropriate protection should be provided for the necessary parts of the die. For example, silicon etching with tetramethylammonium hydroxide (TMAH) cannot be performed with a photoresist masking. Low temperature oxide should be used as a mask in TMAH. It is also known that polyimide film reacts with TMAH solution, therefore, those regions with polyimide films should be well protected. XeF₂ pulse etching is very simple and highly selective for silicon. The drawback of this method is that it is isotropic and therefore it is harder to control the etching profile with the increased surface roughness during long etch cycles. Surface roughness during 400 μm substrate etch limits the resolution to about 20 μm feature size. Deep RIE systems with SF₆ chemistry is a better approach if high accuracy and resolution is needed.

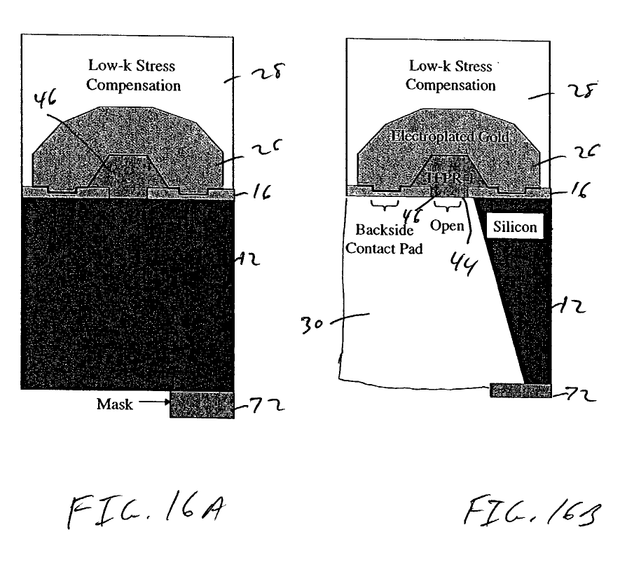

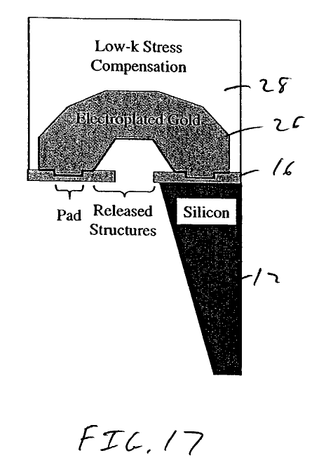

The MEMS IC 10 is placed in an XeF₂-etching station upside down to etch the exposed silicon. Depending on the area and the volume of the exposed Si and the pulse parameters, back side etching might take from 30 minutes to a few hours of etching. This step of the process is illustrated in FIGS. 16A and 16B. FIG. 16A shows the MEMS IC 10 prior to bulk micromachining, and FIG. 16B shows the MEMS IC 10 after bulk micro machining has been performed. During back side etching, all of the silicon underneath the compensated area is removed. This exposes the sacrificial photoresist which is the first thick film photo resist layer 46 and the electrical contact pads accessible from the back side of the MEMS IC 10.

At room temperature, XeF₂ has a sublimation pressure of about 4 Torr. The gas forms HF in the presence of water vapor. Therefore, proper ventilation is necessary. The reaction between silicon and XeF₂ is given below:

2XeF₂+Si?2Xe+SiF₄

The etch has very high selectivity to common thin films including silicon dioxide, silicon nitride, photoresist and aluminum. It consists of a two stage mechanical roughing pump, stainless steel or aluminum etching chamber, a capacitive pressure gauge, pneumatic valves a needle valve. All the pneumatic valves are controlled with a computer. The XeF₂ is metered by using a pressure to the etching chamber. Typical XeF₂ fill-in duration is less than 10 sec, but the time depends on the etching chamber. One of the systems used had a 4 inch wafer processing capability, thus a large etching chamber. The fill-in time for this chamber is more than 45 sec.

It takes approximately 130 of 2 Torr-pulses of XeF₂ to etch 4.7 mm×4.7 mm CMOS chip completely. Each pulse is 200 sec long including the fill-in time.

FIG. 17 illustrates the last step of the process. In this step, the sacrificial photoresist which is the first thick film photo resist layer 46 is removed through open holes in the CMOS membrane. One of the unique features of this process is that it allows the fabrication of various types of sensors and actuators. This step assures the integration of these low-frequency components. Arguably, this step might be the most important innovation brought to the fabrication process.

Integration of chips at the system level and their packaging can no longer be considered independent from the low level fabrication outlined above. Therefore, during the development of the CM-MEMS technology, the integration issues are taken into account.

The CM-MEMS technology allows the integration of all the first four types of devices on a single CMOS die. However, low electron mobility in silicon prevents the high frequency operation of active devices in this medium even the state of the art photolithographic technology is used. On the other hand, by using silicon-germanium heterojunction bipolar transistor technology (SiGe-HBT) transistors with 90 GHz transit frequency (fₜ) and maximum oscillation frequency (fₘₐₓ) have been demonstrated. This level of performance has been achieved by using standard CMOS processing tools integrated with CMOS devices. Although post-processing of these dies are also possible with proper choice of etchant systems, we believe that because of the cost considerations integration of such specialized chips with CM-MEMS fabricated chips are more cost-effective.

Flip-chip integration of active microwave components have been studied as one of the most processing integration methods at high frequencies. Based on these studies several systems have already been announced. The present process for fabricating a MEMS IC 10 can easily be altered to incorporate flip-chip integration of active devices. Most of the current techniques use electroplated gold bumps to bond two substrates together. Usually electroplating requires additional processing. Therefore, increase the cost of the fabrication. However, the proposed process already has the electroplating step. This eliminates the additional cost for integration. Although it is not shown, the flip-chip integration of SiGe or GaAs based circuits can be done after stripping off the second thick film photo resist layer 54 and exposing the seed layer 52. Necessary underfill must be carried out multiple times to fill the large air gap because of the exposed areas of the first thick film photo resist layer 46 underneath the integrated chip. Similarly, other special chips can be integrated with the micromachined CMOS chip in similar manner.

The present invention will now be discussed with reference to the fabrication of a CMOS-based MEMS IC 10 for a tunable capacitor 86. Specifically, the fabrication of a novel thermally actuated tunable capacitor 86 is described.

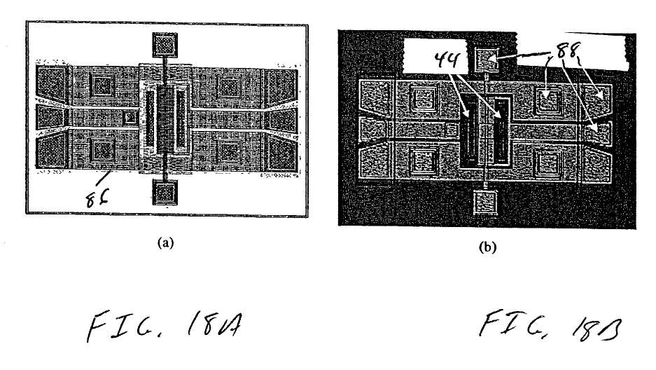

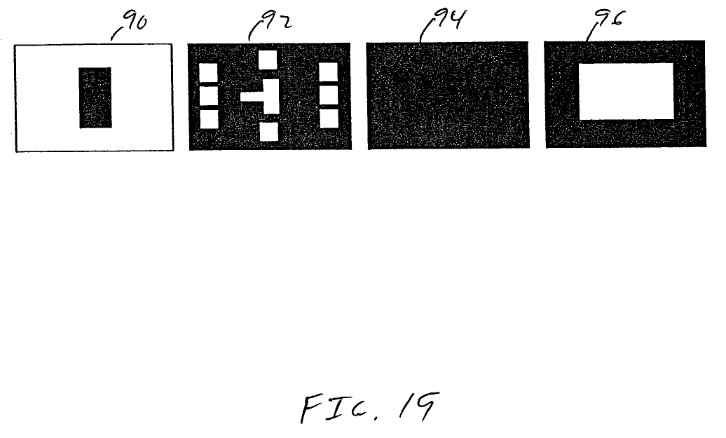

The capacitor is designed by preferably using 1.2 μm, 2poly/2metal CMOS technology. The final layout of the tunable capacitor 86 is shown in FIG. 18A while FIG. 18B shows a fabricated tunable capacitor including openings 44 and the contact pads 88 of the first metal layer 16. The fabricated devices include open holes 44 necessary to remove the sacrificial first thick film photo resist layer 46. All the contact pads 88 shown in FIG. 17B are two sided. That is the contact pads 88 are accessible from both sides of the CMOS membrane 80 after the silicon etch process.

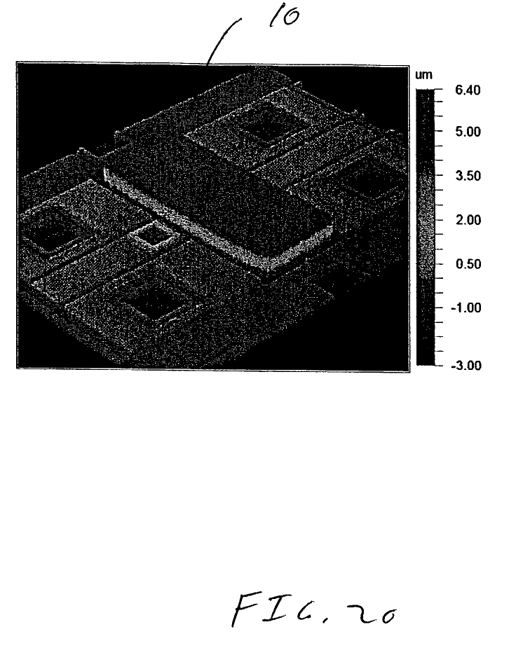

Four low-resolution masks are used for post-processing as shown in FIG. 19. Mask 90 shows a pattern for the first thick film photo resist layer 46 to be applied to the opening 44. Mask 92 shows a pattern for the second thick film photo resist layer 52 for the electroplating portion of the MEMS IC 10 fabrication process. Similarly, mask 94 shows the mask for screen printing during the application of the the polymide layer 28. However, since the capacitor 86 does not use screen-printing, mask 94 is not used. Therefore, mask 94 does not have any features. Mask 96 shows the mask used for back side patterning during the fabrication of the MEMS IC 10.

To fabricate the capacitor 86, two coats of a first thick film photo resist layer are patterned using mask 90. Preferably the first thick film photo resist layer comprises a TFPR having two coats of AZ-P4620 and developed in a 2:1 diluted AZ-400K for 45 sec. The thickness of this layer defines the spacing between the parallel plates 20 and 26.

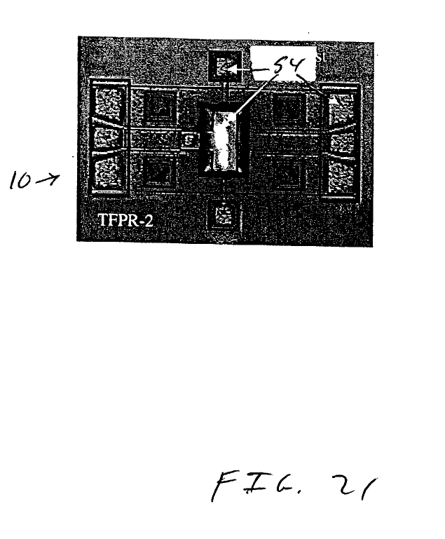

In situ cleaning is performed using preferably 1 kV argon ions for about 15 minutes. Since the beam diameter is smaller than the total MEMS IC 10 area, the MEMS IC 10 should be scanned. A 120 A barrier material, e.g., chromium, is evaporated. FIG. 19B shows the MEMS IC 10 after 3000 A gold is evaporated as a seed layer for electroplating. Since the whole top surface of the MEMS IC 10 is covered with gold, accurate interferometric reading of the 3D profile can be obtained. A 3D model of the surface of the MEMS IC 10 after the seed layer is deposited is included in FIG. 20. FIG. 20 shows a very good first thick film photo resist layer 46 profile with an average thickness of 11.1 μm.

The second thick film photo resist layer 54 is spun and patterned by using the mask 92. It is important to have features on the vertical walls of the first thick film photo resist layer 46 be defined clearly. This is difficult to detect using optical means because of a limited depth of field in optical microscopy. Therefore, preferably longer than normal exposure times should be used to pattern the MEMS IC 10. FIG. 21 shows the patterned second thick film photo resist layer 54 used as a mold.

Gold is then electroplated onto the seed layer to form gold layer 26. The second thick film photo resist layer 54 is stripped with a solution preferably acetone, the plating is characterized with preferably a Wyko Optical Profiler system. An acceptable level of uniformity is obtained on the plated surface, with an average thickness 5 μm. On the other hand, the second metal layer 26 contact area has an average of 2 μm thick gold plating. Then, gold and chromium are stripped to isolate the devices electrically. About 100 μm thick Epo-tek 600 film is screen-printed by using the mask 94. After the polymide layer 28 is cured, another coat of film is deposited, but this time it is cured with a glass superstrate attached. Bonding to an additional superstrate is usually preferred in lab environment because it simplifies handling and eliminates difficulties encountered during measurements.

The back side of the chip is patterned by using Shipley 1813 spun at 5000 rpm and the final mask 96. Then, the exposed silicon is etched from the back side by preferably using a XeF₂-etching station.

In an embodiment of the invention, a novel tunable capacitor 86 is fabricated using the CMOS-based monolithic MEMS IC process. Actuation is based on the thermal expansion differences between the different materials of the capacitor 86 and allows the integration of actuators to the plates which minimizes the overall area.

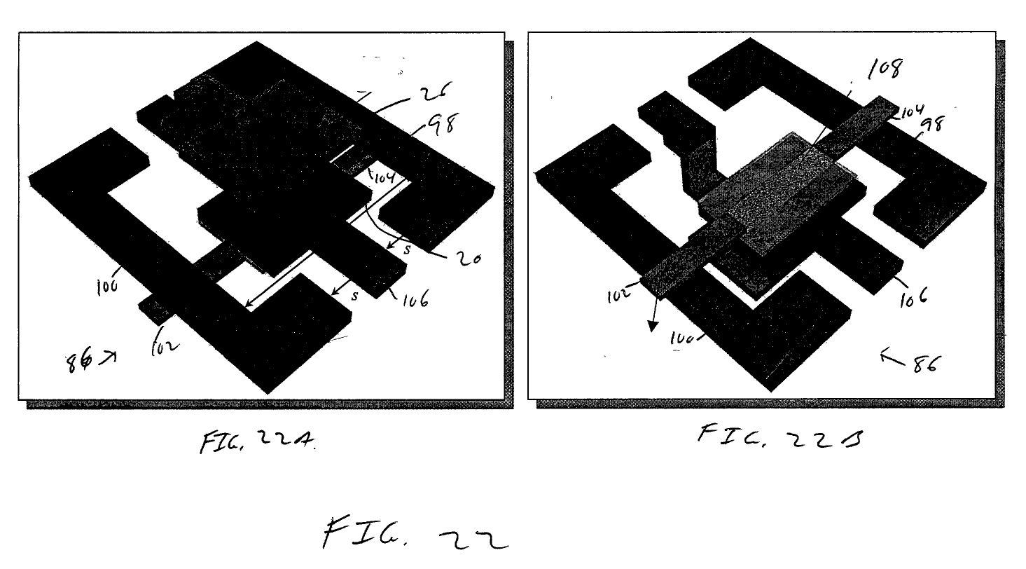

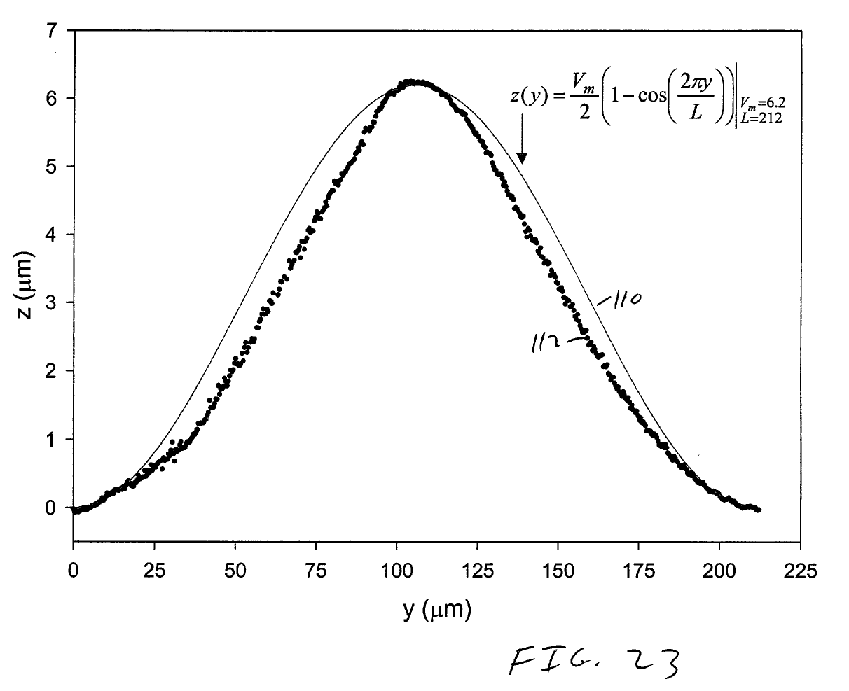

The architecture for the capacitor 86 is illustrated in FIGS. 22A and 22B. The capacitor 92 comprises the gold plate 26 and the second metal plate 20. The gold plate 26 is disposed above the second metal plate 20 and is suported by the polymide layer 28 (not shown) and is attached to supporting member 98 so that it is relatively immobile. In another embodiment of the invention, the gold plate 26 is supported solely by the polymide layer 28. The second metal plate 20 is suspended by three strips or arms 102, 104 and 106. Arms 102 and 104 are supported by supporting members 98 and 100 and comprise the same material as the first metal layer 16. Arm 106 is constructed from the same material as second metal plate 20. The arms 102, 104 and 106 allow the second metal plate 20 to move freely in a vertical direction. Although the second metal plate 20 is described as being connected to three arms, for practical purposes arm 106 can be disregarded because it extends from the second metal plate 20 at one end and hangs freely on the opposing end. Thus, the second metal plate 20 can be considered a fixed-fixed beam (FFB). FIG. 22B shows the capacitor 86 from a bottom side view. Disposed between the arms 102 and 104 supporting the second metal plate 20 is a polysilicon heater 108. The polysilicon heater 108 is located underneath the second metal plate 20.

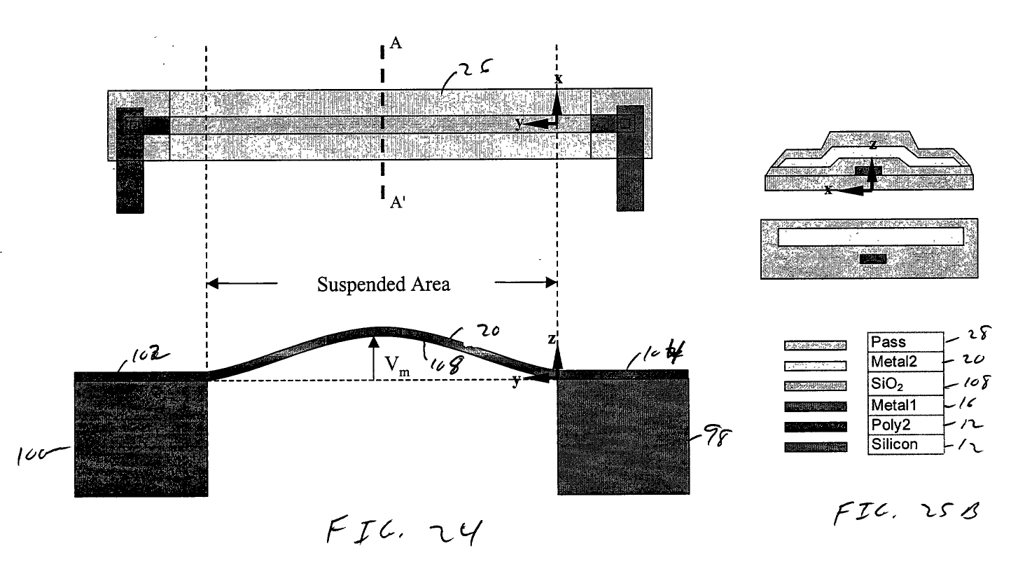

The thermal isolation of the second metal plate 20 is critical to achieve highly efficient actuation. When no power is applied, the internal stress of the thin-films of the polysilicon heater 108 causes the second metal plate 20 to buckle in a well-characterized manner. The direction of the buckling is determined by the stress distribution in the polysilicon heater 108. If the field-oxide is present in the polysilicon heater 108, it assures that the buckling is toward the gold metal plate 26. FIG. 23 shows a two dimensional view of the interferometric measurement of the second metal plate 20. The profile of the beam agrees with the developed theory as shown in FIG. 23 where waveform 110 is the predicted curve, and waveform 112 is the actual curve. Waveform 112 is a close approximation of the predicted curve 110.

A realistic description of the actuator is very difficult because of the interaction between the electrical, thermal, and mechanical domains. Therefore, it is assumed that the second metal plate 20 and the polysilicon heater 108 can be described as a fixed-fixed beam having a uniform cross-section.

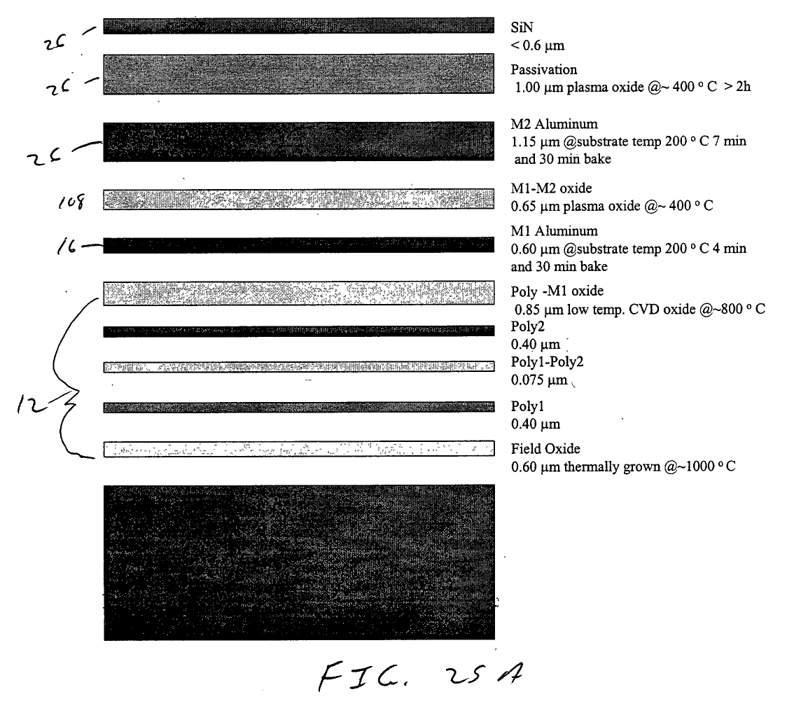

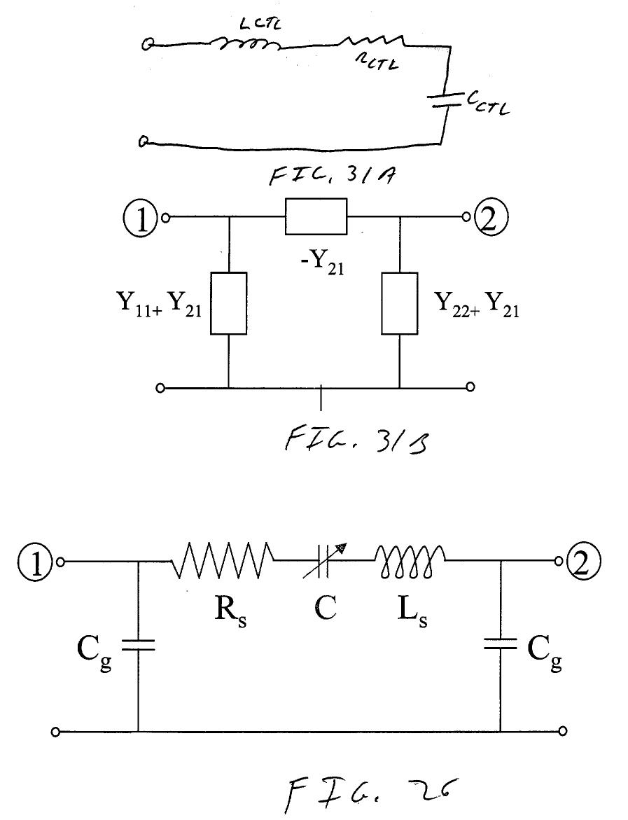

FIG. 24 shows the capacitor 86 modeled as a fixed fixed beam where Vₘ is the maximum amount of deflection at the center of the second metal plate 20. Since it is very difficult to treat the conventional thin-films shown in FIG. 25A a simpler profile is used in 25B where all the SiO₂ layers are assumed to have the same mechanical properties.

After these simplifications, the deflection at the center of a FFB, Vₘ, as illustrated in FIG. 24, can be calculated as:

Vₘ=aₒl

where l is the suspended length of the beam and the coefficient aₒ is given by

$${a}_{o} = \frac{2}{π} \sqrt{ϵ - \frac{{π}^{2}}{3}} {t}^{2}$$

In this equation, the strain of the composite beam, ?, is calculated for the no-power case as:

$$ϵ = \frac{σ}{E} = \frac{l - L}{l}$$

where L is the unreleased length of the FFB. The composite stress, s, and Young's modulus, E, are approximated as follows;

$$σ = \frac{{σ}^{′}}{{τ}^{′}} , E = \frac{{E}^{′}}{{t}^{′}}$$

$${σ}^{′} = {\sum }_{i} \frac{σ}{i} \cdot \frac{t}{i} , {t}^{′} = {\sum }_{i} \frac{t}{i} , {E}^{′} = {\sum }_{i} \frac{E}{i} \cdot \frac{t}{i}$$

In Eq. 5, sᵢ, tᵢ and Eᵢ are the stress, the thickness and Young's modulus in the i^{.th} film, respectively (see FIG. 25B). The longitudinal stress values for each thin film can be determined by using integrated MEMS test structures on the same die. The material properties for the thin films are given in Table 3 where the measured values of residual stress, s, Young's modulus, E, and Poisson's ratio are provided.

TABLE 3

| Layer | s (MPa) | E (GPa) | v |
|---|---|---|---|
| BPSG | −40 | 20 | — |
| BSG | −37 | 65 | 0.2 |
| S iN | 82 | 97 | .0.13 |
| Pol | −134 | 52 | 0.2 |
| Metal1 | −73 | 50 | 0.3 |
| Metal2 | 30 | 55 | 0.2 |

When the power is applied, equation 2 should be modified in order to take thermally induced changes. As a first order approximation, the temperature is assumed uniform over the beam. This leads to equation 6:

$$ϵ = \frac{σ}{E} + α \cdot Δ T ( P )$$

where a is the coefficient of thermal expansion (CTE) of the composite beam and ?T(P) is the temperature change in the beam when a power of P is applied to the polysilicon heater 108.

The most difficult part of the simplified problem is the determination of the relation between ?T and P. The calculation of average temperature requires the solution of a complicated boundary problem, which includes different types of thermal dissipation e.g., conduction, radiation and convection, and nonlinear behavior of the polysilicon. Therefore, in many cases, empirical relations are used. At small power levels, the relation can be described with a linear relation as

ΔT(P)=γ·P

where P is in mWs and ? is a constant with a unit of K/mW. This coefficient applies to the 2.0 μm CMOS process.

Once the thermal effects are included in the system, equation 1 can be written as

Vₘ=aₒ(P)l

Based on this simplified treatment, the efficiency of a thermally actuator Yₜₕₑᵣₘₐₗ, is defined as

$${γ}_{thermal} = \frac{Δ Vm}{Δ P}$$

The maximization of this efficiency is crucial for low-power applications. Consequently, if ? is known for a specific FFB, then equation 8 can be used to calculate Vₘ the deflection at the center of a beam. This parameter determines the overall profile of the FFB, which is given as

$$z ( y ) = \frac{{}^{v} m}{2} ( 1 - cos ( \frac{2 π y}{L} ) )$$

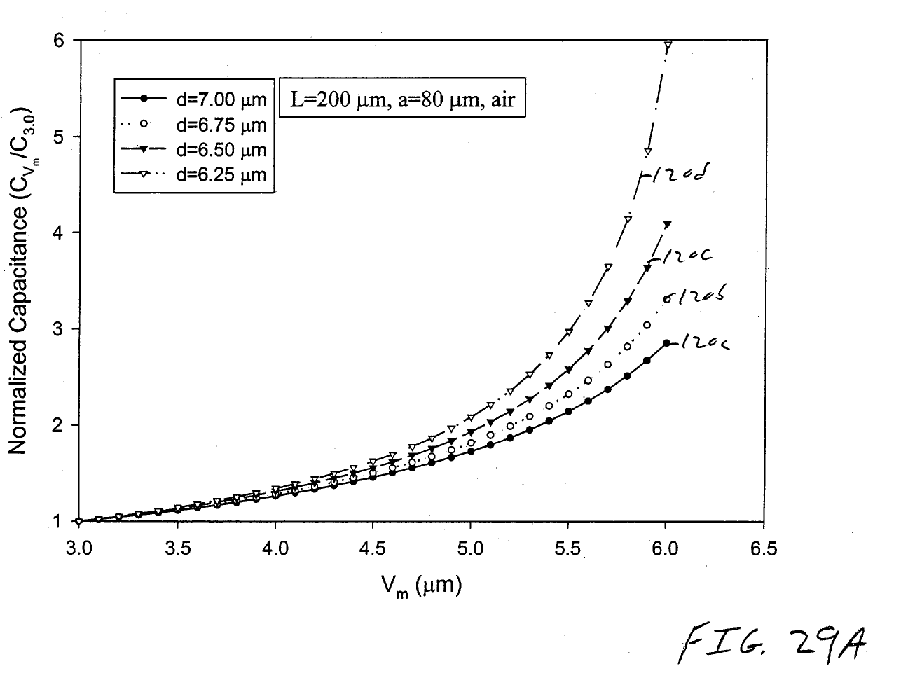

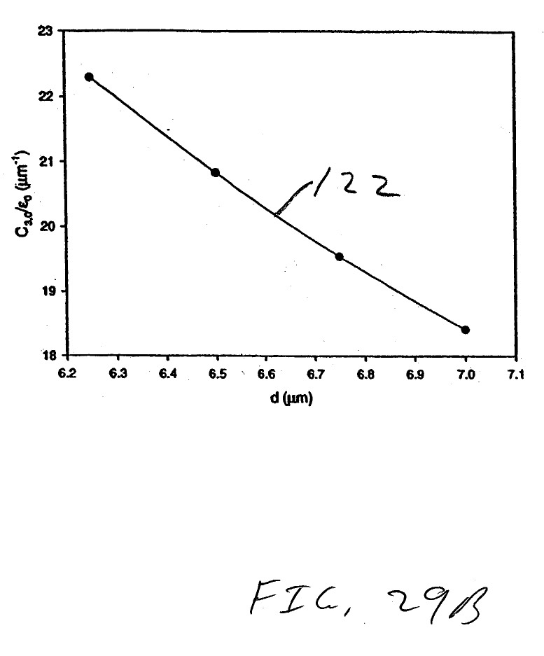

The curve for P=0 is included in FIG. 29B for the fabricated systems.

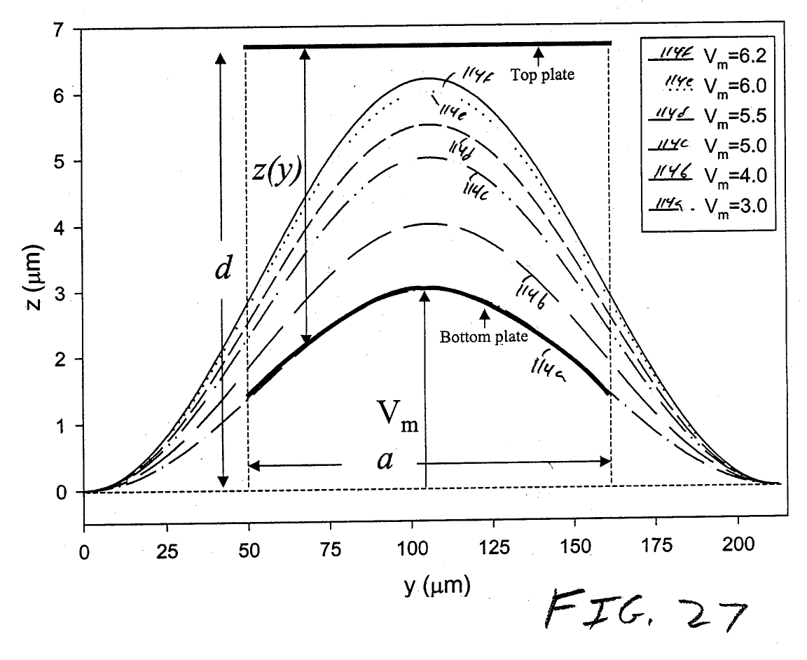

An equivalent electrical model of the micromachined tunable capacitor 86 is given in FIG. 26 where R_{S} is due to the resistive losses in the plates 20 and 26, L_{S} is the inductance of the arms 102 and 104 and C_{g} is the parasitic capacitance between the plates 20 and 26. A scalable physical model of the tunable capacitor 86 is developed based on the following assumptions: equation 10 describes the beam profile accurately for 0<P<Pₘₐₓ, i.e. when Eq. 7 is valid; the profile function in Eq. 10 is valid for every x; the gold plate is assumed planar and parallel to the MEMS IC 10; fringe fields contributing to capacitance C and C_{g} are assumed negligible; all capacitances due to discontinuities are assumed small and are neglected.

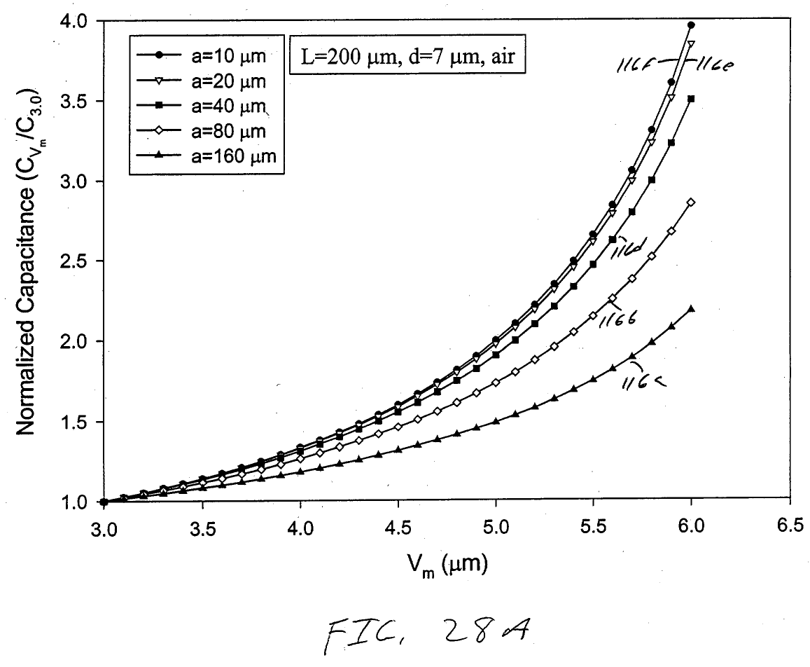

The capacitance can be calculated with the variables shown in FIG. 27. The calculated profiles of the bottom-plate for several waveforms 114 of Vₘ values are shown. In general, only certain portions of the FFB may be covered with second metal layer 20. Since maximum change occurs at the center of the beam, a length of a<L positioned at the center of the beam is assumed to be metalized. Then, the capacitance per unit length along x is given by:

$$C = \frac{E}{o} {\int }_{\frac{L - a}{2}}^{\frac{L + a}{2}} \frac{1}{z ( y )} ⅆ y$$

where the distance between the plates, z(y) is given as

$$z ( y ) = d - \frac{{V}_{m}}{2} ( 1 - cos ( \frac{2 π y}{L} ) )$$

where d is the distance between the second metal plate 20 surface and the gold plate 26. Therefore,

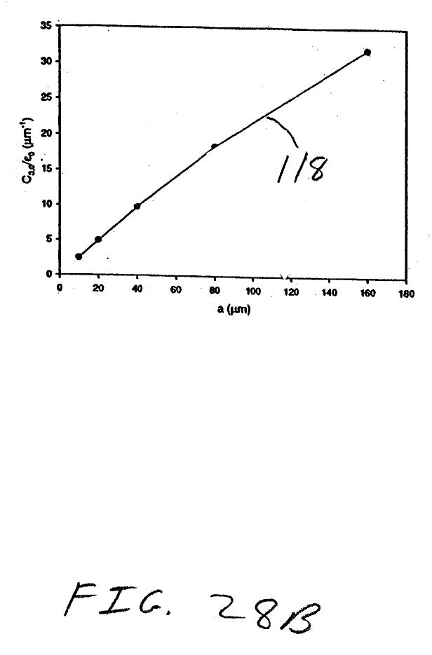

The effects of parameters are calculated based on this equation. FIG. 28A

$$C {=}_{n} \sqrt{d ( d - {V}_{m} )} \int arctan \int \frac{( d - {V}_{m} ) \cdot tan ( \frac{π ( L - a )}{2 L} )}{\sqrt{d ( d ( - {V}_{m}^{o}} )} ) - arctan ( \frac{( d - {V}_{m} ) \cdot tan ( \frac{π ( L - a )}{2 L}}{\sqrt{d ( d - \frac{V}{m}} )} )$$

shows the calculation results for various plots 112 representing values of a<L=220 μm. For FIG. 28A, plot 116 shows that the smaller the plate area, the smaller the plate density. As expected the capacitance change is maximum for narrow strips placed at the center of FFB. If the spacing between the plates 20 and 26, d, is 7.0 μm and the maximum deflection (at P=0) is 6.0 μm, are assumed 3.0 μm actuation at the center can yield as high as 4:1 capacitance ratios. However, narrow strips have very small absolute capacitance densities as shown by plot 118 in FIG. 28B. Thus, to achieve a large capacitance, the area of the plates should be increased.

The minimum spacing between plates (d−V_{m,max}) is an important parameter in the calculations. A 1 μm of minimum spacing, used in the calculations, is very conservative. One advantage of having a large minimum distance is that the value of the capacitance can be controlled more accurately.

The minimum spacing between the plates is varied while the strip width, a, is fixed at 80 μm. The normalized capacitance for a 3 μm actuation at the center is given in FIG. 29A where the plots 120a through 120d represent different distances between the plates 20 and 26. A modest capacitance ratio of 2.8 for d−V_{m,max}=1 μm increases more than twice when the minimum distance decreased to 0.25 μm. The change in capacitance density is not that impressive, it is less than 30% for the same case as shown by plot 122 in FIG. 29B.

Power requirements rather than the voltage determines the maximum actuation that can be achieved in a system. The mechanical efficiency of the actuator is defined as

$${γ}_{mechanical} = \frac{Δ C}{Δ {V}_{m}} ,$$

and depends on the spacing between the plates, d−Vₘ. Accordingly, y_{mechanical} of the actuator can be optimized independently from yₜₕₑᵣₘₐₗ, by decreasing the minimum distance between the plates 20 and 26. Based on equation 13, capacitance ratios larger than 10:1 can be obtained with less than 3 μm actuation at the center of the beam.

Performance of the tunable capacitor 86 is limited by parasitic components. An important parameter is the resistive losses in the system. With an increased area, the resistive losses and the parasitic reactive components become significant.

There are several different IC layouts that can meet a given set of requirement e.g., Cₘₐₓ, Cₘₐₓ, Cₘᵢₙ ratio and the maximum available power to the actuator. The series resistance, R_{S}, is calculated using worst case estimates. By using the dimensions given in FIG. 28A, the resistance can be calculated as

$$\begin{matrix}\frac{R}{S} = \frac{R}{top} + \frac{R}{bottom} \\ = ( \frac{R}{contact} + R \frac{Au}{sheet} \cdot ( \frac{{l}_{1 + d}}{{w}_{1}} + \frac{{l}_{2}}{a} ) ) + R \frac{Metal2}{sheet} \cdot ( \frac{{l}_{1}}{{w}_{1}} + \frac{{l}_{2}}{a} )\end{matrix}$$

where R_{contact} is the contact resistance between the second metal plate 20 and the gold plate 26, R^{AU} and R^{Metal2} are the sheet resistances of the plates 26 and 20, respectively. Since the space between the plates is filled with air, the inter-plate losses can be neglected. This is important because inter-plate loss is the dominant loss mechanism in junction and MOS-type capacitors.

The sheet resistance of the second metal plate 20 is about 0.03 O/sq. The thickness of the gold plate 26 varies between 2 μm and 5 μm. Consequently, the sheet resistance changes depending on the plating thickness. In a worst case, it would be about 2.35×10⁻⁸/2×10⁻⁶=0.01 O/sq. The contact resistance is more difficult to estimate. However, for a 40×40 μm contact area, resistance values less than 0.1 O are regularly obtained by commercial gold-bumping processes.

The series inductance, Lₛ, and the shunt capacitors, C_{g}, are important to find the self resonance frequency of the tunable capacitor 86. Only the self inductance of the metal strips 102 and 104 is calculated. The self-inductance of a flat-wire with length, l, width, w, and thickness, t, is given by

$${l}_{self} ( l , w , t ) = 2.0 \times {10}^{- 3} \cdot l \cdot [ In ( \frac{20 l}{w + t )} + 0.5 + 0.2235 ( \frac{w + t}{l} ] )$$

The total self-inductance is then calculated as

Lₛ=Lₜₒₚ+L=(L_{self}(l₁+d.w₁,t^{Au})+l_{self}(l₂,a,t^{Au}))+(L_{self}(l₁,w₁,t^{Metal2})+L₂,a,t^{Metal2})).

Additional parasitic inductances such as discontinuity, coplanar waveguide mode, and mutual inductances, may add up to a comparable value to the one obtained from Equation. 17.

The capacitance to ground, C_{g}, is calculated for the second metal plate only. The calculation assumes that the plate is planar, and the capacitance contribution from the top surface of top plate can be approximated with the contribution from the same area of the bottom plate. The quasi-static capacitance for a finite-ground coplanar transmission line is given as:

$${C}_{CTL} ( a , b , c , l ) = 4 \cdot {e}_{o} \cdot l \cdot \frac{K ( {k}^{′} ( a , b , c ) )}{K ( K ( A , b , c ) )} ( F ) ,$$

where a is the width of the signal line, b is the ground-to-ground separation, c is the overall width of the ground planes and l is the length of the transmission line. In this equation, K(k) is the complete elliptic integral of the first kind and k is the argument of the integral (k′ is defined as k′=vl−k²) calculated by

$$K ( a , b , c ) = \frac{c}{b} \sqrt{\frac{{b}^{2} - {a}^{2}}{{c}^{2} - {a}^{2}}}$$

If the physical parameters illustrated in FIG. 28A are used, C_{g} is calculated as

$${c}_{g} = \frac{1}{2} ( {C}_{CTL} ( {w}_{1} , L , L + 2 {w}_{2} , 2 l , + d ) + {C}_{CTL} ( a , L , L + 2 {w}_{2} , {l}_{2} ) )$$

The quality factor based on this model can be written as

$$Q = \frac{1}{ω C \cdot {R}_{s}} .$$

The quality of such a device is conductor loss limited. Therefore, they are suitable for high-frequency applications. For operation frequencies above 10 GHz, the sheet resistance in equation 15, is no longer valid. Nonetheless, by multiplying the sheet resistance by a frequencydependent term (e.g. a^{β,} with appropriate constants a and β), it is possible to extend the formula to higher frequencies. Additionally, the self-resonance frequency of a tunable capacitor is important e.g., it can be used at frequencies f<<f_{c}. It is given by

$${f}_{c} = \frac{1}{\sqrt{{L}_{S} C}} .$$

Planar inductors are usually limited by the self-resonant frequencies, because of high parasitic capacitances. Mechanical tunable capacitors, on the other hand, have much simpler geometry and smaller parasitic components. This allows a wider range of applications for tunable capacitors.

The present invention will now be discussed with reference to an exemplary tunable capacitor having the design requirements of Cₘₐₓ=2 pF, Cₘₐₓ/Cₘᵢₙ=10, _{—}>50 at 2.4 GHz and Pₘₐₓ<50 mW.

Based on the simplified models of an actuator and tunable capacitor, the capacitance ratio and the capacitance value are maximized by decreasing the distance, (d−V_{m,max}). Distances less than 1 μm are difficult to achieve with a high yield. Therefore, from a fabrication point of view, the thickness of the cavity, d, is chosen to be less than or equal to the estimated V_{m,max}. This allows very small or no separation under no-power condition. During operation, the actuator should be always powered to assure the desired value of the capacitance. Therefore, although it is not possible to fabricate devices with 0.1 μm minimum. separation under zero-power, the equivalent operation can be easily achieved under low-power operation conditions.

Table 4 characterizes two capacitors satisfying these requirements. Both capacitors occupy larger than 0.2 mm² of plate area and employ the same amount of actuation and high Y_{mechanical}. Specifically, table 4 shows a comparison between two capacitors that have identical capacitance ratios and maximum capacitance.

TABLE 4

| | A | B |
|---|---|---|
| L(μm) | 300.0 | 500.0 |
| a(μm) | 100.0 | 200.0 |
| d(μm) | 6.0 | 6.0 |
| dV_{m,max}(μm) | 0.1 | 0.1 |
| l₁(μm) | 50.0 | 50.0 |
| W₁, (μm) | 50.0 | 50.0 |
| l₂(μm) | 700.0 | 400.0 |
| Cₘₐₓ(pF)) | 2.0 | 2.0 |
| Cₘₐₓ/Cₘᵢₙ | 10.5 | 9.8 |
| ?Vₘ(μm) | 3.0 | 3.0 |

A quality factor for 50 at 2.4 GHz requires a series DC resistance of 0.66 O or smaller. The resistances for these cases A and B are given as (R_{contract}+0.321) O and (R_{contract}+0.121 O, respectively. Even contact resistances as high as 0.5 O are acceptable to satisfy the quality requirement. This shows that the contact resistance may become the dominant factor in this design. A surface cleaning is essential to obtain small resistance values. In a standard 2.0 μm CMOS process, contact resistances of 0.55+0.15 O are regularly achieved for a 2×2 μm contact area. In this case, the contact area is 40×40 μm, therefore, at least 10 times smaller values of R_{contact} are possible. Even assuming R_{contact} as 0.15 O the design A can reach quality factors as high as 70, and 170 at 2.4 GHz and 1 GHz, respectively. Design B has the quality factors of 122 and 293 at 2.4 GHz and 1 GHz, respectively.

The frequency response of the tunable capacitors A and B is measured with a HP 8510C network analyzer. A SOLT (Short-Open-Line-Thru) probe-tip calibration is performed using calibration substrate in the 0.1-50 GHz frequency-range.

The calibration substrate is used to extend the reference plane to the probe tips. Although it is accurate for large structures, it is not sufficiently accurate for measuring small devices and devices on a lossy substrate. If the series parasitics are negligible, a simple procedure, called y-parameter subtraction, can be used to de-embed shunt parasitics. This requires an additional measurement using the same setup with the DUT (device-under-test) replaced with the open. Then, the y-parameters are subtracted from the measurement with the DUT. If the series parasitics are not negligible, the setup with the DUT replaced with the shorts is used for the z-parameter subtraction.

FIG. 30 shows a tunable capacitor 86 prior to the application of the seed layer for the CM-MEMS process. In order to obtain an accurate measurement of the tunable capacitor 86, the reference planes should be extended approximately 200 μm toward the capacitor 86. A simple three-step method or the multiline calibration can be employed for de-embedding these transmission line sections. In both cases, additional test structures should be fabricated on the same die.

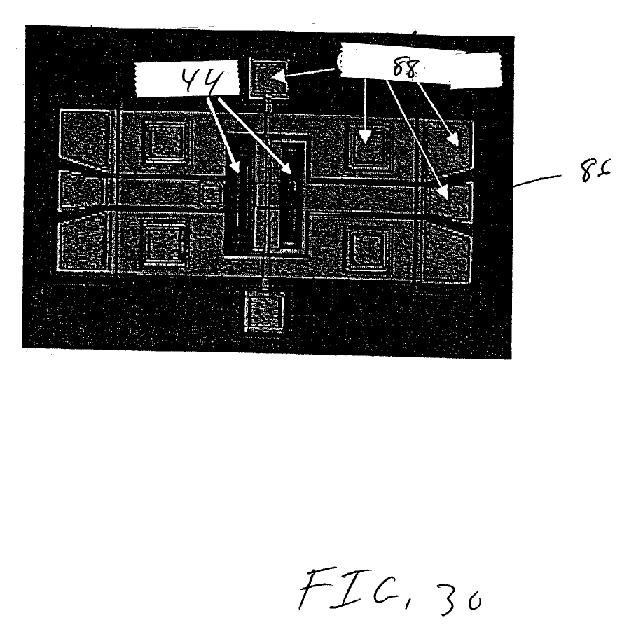

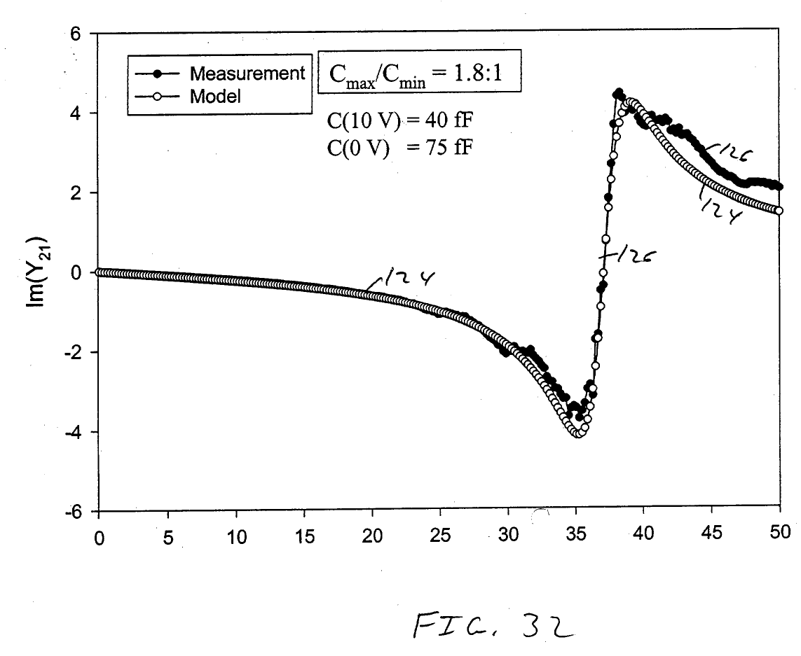

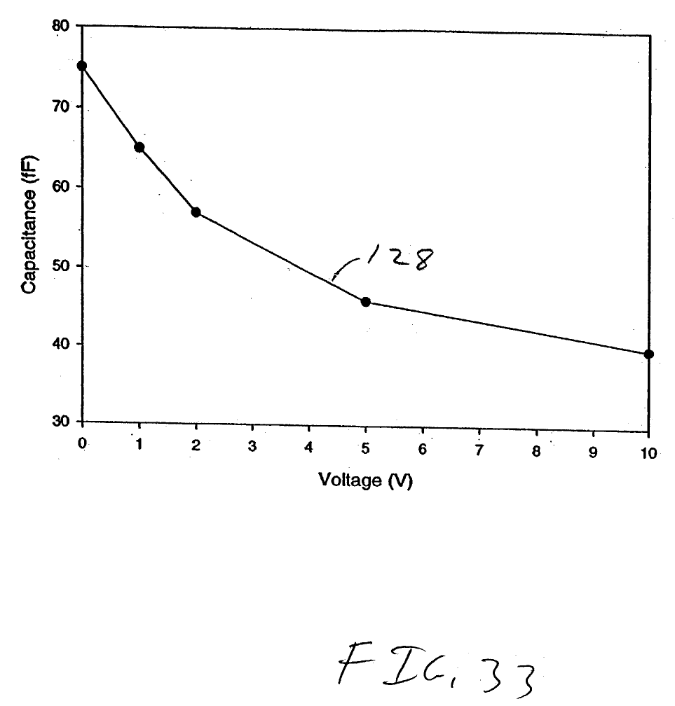

The de-embedding of the pads and coplanar transmission lines are performed by subtracting the parasitics of corresponding transmission line sections as shown in FIGS. 31A and 31B. In FIG. 31A parasitic elements due to the contact pad and transmission line section that are used to de-embed the capacitance measurements. With reference to FIG. 31B, deembedded s-parameters are converted into y-parameters to isolate the shunt and the series branch of the parasitic components shown in FIG. 32. The calculation is based on the independent measurement and characterization of coplanar transmission lines on the same die. The extracted RLGC model of the transmission lines is given by R=6.4 O/cm, L=2.84 nH/cm, G=0 S/cm, C=1.09 pF/cm. These values are used to calculate the lumped parasitics shown in FIG. 31A.

Two-port S-parameters for different various actuation conditions are taken in the 0.1-50 GHz frequency range. To determine the performance of the series branch, the y-parameters of the de-embedded system is used to isolate the series branch impedance. As illustrated in FIG. 31B, Y₂₁ represents the overall response of the serial branch. The capacitance is given by:

$$c = \frac{Im ( - {Y}_{21} )}{ω}$$

The parasitic components, shown in FIG. 32, can be found using circuit optimization. By using Sonnet 3D EM suite, an optimization process is performed for the preliminary data shown in FIG. 32 where plot 124 is the measured curve fit for the tunable capacitor 86, and plot 126 is the theoretical curve fit for a tunable capacitor. The design has L=200 μm, a=200 μm and d=10.4 μm with V_{m,max}=6.2 μm. This gives a capacitance of 5 fF at P=O. The parasitics dominate the parallel plate capacitance. The resulting curves for the measured and theoretical values for the tunable capacitor 92 is shown in FIGS. 32 and 33. In FIG. 33, plot 128 shows the measured capacitance change for a thermally actuated tunable capacitor.

Those skilled in the art can now appreciate from the foregoing description that the broad teachings of the present invention can be implemented in a variety of forms. Therefore, while this invention can be described in connection with particular examples thereof, the true scope of the invention should not be so limited since other modifications will become apparent to the skilled practitioner upon a study of the drawings, specification and the following claims.

What is claimed is:

1. A semiconductor fabrication method using a CMOS based micro-electromechanical system (MEMS) technology, comprising:
fabricating a CMOS circuit layout on a silicon substrate;
depositing a first thick film photo resist layer on said CMOS circuit layout;
forming a seed layer on said seed layer on said first thick film photo resist layer;
depositing a-second thick film photo resist layer on selected portions of said seed layer to form a mold pattern;
electroplating a conductive layer on said mold pattern;
removing selected portions of said seed layer;
applying a stress compensation material over said conductive layer;
etching a back side surface of said silicon substrate to remove areas not covered by a mask layer; and
removing said first thick film photoresist layer via openings in said CMOS circuit layout.

2. The method of claim 1, wherein the CMOS circuit layout is fabricated using a double poly/double metal having a thickness of 2 um.

3. The method of claim 1, wherein the CMOS circuit layout is fabricated using a double poly/double metal having a thickness of 1.2 um.

4. The method of claim 1, wherein said second thick film photo resist layer is thicker than said second thick film photo resist layer.

5. The method of claim 1, wherein said first thick film photo resist layer is a sacrifical layer.

6. The method of claim 1, wherein said seed layer comprises at least one of a gold and chromium alloy adapted to prevent oxidation from occurring between two exterior metals.

7. The method of claim 1, wherein said seed layer comprises at least one metal selected from the group consisting of chromium, nickel and titanium.

8. The method of claim 1, wherein said step of electroplating comprises applying films of gold on said second thick film photo resist layer.

9. The method of claim 1 wherein said step of stripping comprises applying acetone to said second thick film photo resist layer.

10. The method of claim 1, wherein said step of applying stress compensation comprises applying layers of a polymide to said CMOS circuit layout.

11. The method of claim 1, wherein said step of etching comprises applying XeF2 to the back side of the silicon substrate.

12. The method of claim 1, further comprising:
performing bulk micromachining to remove selected portions of said silicone substrate.

13. The method of claim 1, wherein said semiconductor fabrication method provides at least one of a capacitor, a filter, and a transmission line.

14. A tunable micro electromechanical capacitor, comprising:
a first plate;
a second plate disposed opposite said second plate;
at least one arm adapted to support said second plate, said at least one arm including a polysilicon material disposed between said second plate and said at least one arm, said at least one arm providing thermal actuation for said second plate.

15 The tunable capacitor of claim 14, wherein said first plate is comprised of gold.

16. The tunable capacitor of claim 14 wherein at least one of said at least one arm and said second plate is comprised of aluminum.

17. The tunable capacitor of claim 14, wherein said first plate is fixedly suspended above said second plate.

18. The tunable capacitor of claim 14, wherein said first and second plates are in initial contact.

19. The tunable capacitor of claim 14, wherein said at least one arm is connected to at least one supporting member.

20. The tunable capacitor of claim 14, wherein said second plate moves away from said first plate when a voltage is induced in said polysilicon material of said at least one arm.

21. The tunable capacitor of claim 20, wherein a distance between said first and second plates is determined by the voltage induced in said polysilicon material of said at least one arm.

22. The tunable capacitor of claim 14, wherein said first and second plates comprise thin film metal plates.

23. A method of fabricating a micro electromechanical integrated circuit, comprising:
providing a substrate;
applying a first metal layer to said substrate;
applying a first thick film photo resist layer to said substrate, said first thick film photo resist layer being adapted to cover openings in said first metal layer;
applying a seed layer to said first thick film photo resist layer; and
applying a second thick film photo resist layer to said seed layer.

24. The method of claim 23, further comprising:
electroplating a gold layer on said second thick film photo resist layer;
stripping said second thick film photo resist layer from said seed layer;
evaporating said seed layer;
providing a polymide layer over said electroplated gold;
removing a portion of said substrate via bulk micromachining; and
removing said first thick film photo resist layer via surface micromachining.

25. The method of claim 23, wherein said polymide layer provides structural support for said bulk micromachined portion of said substrate.

26. The method of claim 23, wherein the portion of said bulk micromachined substrate is substantially flexible and adapted to move in a vertical direction.
